(19) United States
(12) Patent Application Publication
(10) Pub. No.: US 2026/0068417 A1
(43) Pub. Date: Mar. 5, 2026

(54) ELECTROLUMINESCENT DEVICE AND ELECTRONIC DEVICE INCLUDING THE SAME

(71) Applicant: Samsung Electronics Co., Ltd, Suwon-si (KR)

(72) Inventors: Junho LEE, Suwon-si (KR); Kwang Hee KIM, Suwon-si (KR); Jae Yong LEE, Suwon-si (KR); Ji Hyun MIN, Suwon-si (KR)

(21) Appl. No.: 19/314,378

(22) Filed: Aug. 29, 2025

(30) Foreign Application Priority Data
Aug. 30, 2024 (KR) 10-2024-0117948

(51) Int. Cl. H10K 50/115; H10K 50/15; H10K 50/16; H10K 50/17; H10K 50/18; H10K 71/15; H10K 85/20

(52) U.S. Cl. CPC H10K 50/115; H10K 71/15; H10K 85/20; H10K 50/15; H10K 50/16; H10K 50/17; H10K 50/171; H10K 50/18; H10K 50/181

(57) ABSTRACT

An electroluminescent device includes a first electrode and a second electrode, which are spaced apart from each other (e.g., facing each other), and an emission layer disposed between the first electrode and the second electrode. The emission layer is configured to emit first light having a predetermined peak emission wavelength, and includes a semiconductor nanoparticle and a carbon nanoparticle. The carbon nanoparticle has a dimension of greater than or equal to about 2 nm and less than or equal to about 50 nm.

### CROSS-REFERENCE TO RELATED APPLICATION

This application claims priority to Korean Patent Application No. 10-2024-0117948 filed on Aug. 30, 2024, and all the benefits accruing therefrom under 35 U.S.C. § 119, the content of which in its entirety is herein incorporated by reference.

### BACKGROUND

### 1. Field

The present disclosure relates to an electroluminescent) device, and a display device including the electroluminescent device.

### 2. Description of the Related Art

A semiconductor nanoparticle (e.g., a semiconductor nanocrystal particle) having a size in the nanometer range may exhibit luminescent properties. For example, a quantum dot including a semiconductor nanocrystal may exhibit a quantum confinement effect. The light emission from the semiconductor nanoparticle may occur when an electron in an excited state resulting from light excitation or an applied voltage moves from a conduction band to a valence band. The semiconductor nanoparticle may emit light of a desired wavelength region by adjusting a size of the semiconductor nanoparticle, a composition of the semiconductor nanoparticle, or a combination thereof. The semiconductor nanoparticle may be used, for example, in a light-emitting device (e.g., an electroluminescent device) or a display device including the electroluminescent device. There remains a need for an improved light-emitting device.

### SUMMARY

An embodiment provides a light-emitting device that emits light, for example, by applying a voltage to a nanostructure (e.g., a semiconductor nanoparticle such as a quantum dot), for example with or without a separate irradiation light source.

An embodiment provides a display device (e.g., a quantum dot-light-emitting diode (QD-LED) display device) that includes a semiconductor nanoparticle such as a quantum dot as a component of an emission layer in a pixel configuration (e.g., in a configuration of a blue pixel, a red pixel, a green pixel, or a combination thereof).

An embodiment provides a method of manufacturing the light emitting device.

In an embodiment, an electroluminescent device includes a first electrode and a second electrode, which are spaced apart (e.g., facing each other) from each other; and an emission layer disposed between the first electrode and the second electrode. The emission layer is configured to emit a first light having a predetermined peak emission wavelength, the emission layer includes a semiconductor nanoparticle and a carbon nanoparticle, and the carbon nanoparticle has at least one dimension that is greater than or equal to about 2 nanometers (nm) and less than or equal to about 50 nm.

The carbon nanoparticle may be non-luminous. The carbon nanoparticle may not emit light as being irradiated with light having a wavelength of from about 390 nm to 580 nm, about 400 nm to 560 nm, about 440 nm to 540 nm, about 460 nm to 520 nm, about 480 nm to 500 nm, or a combination thereof.

The dimension may be a thickness of the carbon nanoparticle.

The dimension may be a diameter of the carbon nanoparticle.

The semiconductor nanoparticle may emit the first light by a voltage applied between the first electrode and the second electrode.

The predetermined peak emission wavelength may be present in a blue wavelength region. The predetermined peak emission wavelength or the blue wavelength region may be greater than or equal to about 440 nm (or greater than or equal to about 450 nm) and less than or equal to about 475 nm, or less than or equal to about 470 nm.

The predetermined peak emission wavelength may be present in a green wavelength region. The predetermined peak emission wavelength or the green wavelength region may be greater than or equal to about 500 nm (for example, greater than or equal to about 515 nm) and less than or equal to about 580 nm (or less than or equal to about 540 nm).

The predetermined peak emission wavelength may be present in a red wavelength region. The predetermined peak emission wavelength or the red wavelength region may be greater than or equal to about 600 nm (or greater than or equal to about 615 nm) and less than or equal to about 680 nm (or less than or equal to about 650 nm).

The first light may have a full width at half maximum (FWHM) that is greater than or equal to about 5 nm (or greater than or equal to about 10 nm) and less than or equal to about 50 nm (or less than or equal to about 40 nm).

The semiconductor nanoparticle may not include cadmium. The semiconductor nanoparticle may not include lead, mercury, or a combination thereof.

In an embodiment, the semiconductor nanoparticle may include a first semiconductor nanocrystal and a second semiconductor nanocrystal having a composition different from that of the first semiconductor nanocrystal. The semiconductor nanoparticle may have a core-shell structure including a core and a shell disposed on the core. The core may include the first semiconductor nanocrystal. The shell may include the second semiconductor nanocrystal.

The semiconductor nanoparticle or the first semiconductor nanocrystal may include a silver indium gallium sulfide, an indium phosphide, an indium zinc phosphide, a zinc chalcogenide, or a combination thereof.

The second semiconductor nanocrystal or the shell may include a zinc chalcogenide. The zinc chalcogenide may include zinc; and selenium, sulfur, or a combination thereof. The zinc chalcogenide may include a zinc selenide, a zinc sulfide, a zinc selenide sulfide, a zinc telluride, or a combination thereof.

The semiconductor nanoparticle may have a size that is greater than or equal to about 3 nm, greater than or equal to about 5 nm, greater than or equal to about 7 nm, greater than or equal to about 8 nm, greater than or equal to about 9 nm, or greater than or equal to about 10 nm. The size of the semiconductor nanoparticle may be less than or equal to about 30 nm, less than or equal to about 20 nm, less than or equal to about 15 nm, less than or equal to about 12 nm, or less than or equal to about 10 nm. The size may be an average size.

The carbon nanoparticle may include a carbon black, a graphite nanopowder, a graphene nanoparticle, a graphene oxide nanoparticle, or a combination thereof. The carbon nanoparticle may be a carbon black. The carbon nanoparticle may be a graphene nanoparticle, a graphene oxide nanoparticle, or a combination thereof.

The carbon nanoparticle may be a sheet-like or plate-shaped particle having a thickness of 2 nm to 50 nm. A maximum dimension of the sheet-like or plate-shaped particle may be less than or equal to about 1 micrometer (μm), or less than or equal to about 900 nm and greater than or equal to about 10 nm.

The carbon nanoparticle or the carbon black may include amorphous carbon or paracrystalline carbon. The carbon nanoparticle may be a crystalline carbon nanoparticle. The carbon nanoparticle (or the carbon black) may have a (mean) dimension (e.g., particle diameter) that is greater than or equal to about 5 nm, or greater than or equal to about 10 nm and less than or equal to about 45 nm, or less than or equal to about 40 nm.

The carbon nanoparticle (or the carbon black) may have a specific surface area that is greater than or equal to about 20 square-meters per gram (m²/g), greater than or equal to about 30 m²/g, and less than or equal to about 1500 m²/g, less than or equal to about 1200 m²/g, less than or equal to about 1000 m²/g, less than or equal to about 800 m²/g, or less than or equal to about 500 m²/g.

The carbon nanoparticle (or the carbon black) may be electrically conductive. The carbon nanoparticle may have an intrinsic resistivity that is less than or equal to about 150 ohm·cm, for example, less than or equal to about 100 ohm·cm, less than or equal to about 50 ohm·cm, or less than or equal to about 10 ohm·cm.

The carbon nanoparticle may have an intrinsic resistivity that is greater than or equal to about 0.001 ohm·cm, greater than or equal to about 0.005 ohm·cm, or greater than or equal to about 0.1 ohm·cm.

The carbon nanoparticle may have a carbon content that is greater than or equal to about 95 wt %, or greater than or equal to about 98 wt % and less than or equal to about 99.9 wt %, or less than or equal to about 99.7 wt %.

The carbon nanoparticle may have a dibutyl phthalate (DBP) absorption of greater than or equal to about 10 cc/100 g, for example, greater than or equal to about 50 cc/100 g and less than or equal to about 2000 cc/100 g, or less than or equal to about 1800 cc/100 g.

The emission layer may include a plurality of the carbon nanoparticles.

The emission layer may include an assembled body of a plurality of carbon nanoparticles. The assembled body may have at least one dimension that is greater than or equal to about 30 nm, or greater than or equal to about 50 nm and less than or equal to about 500 nm, less than or equal to about 300 nm, or less than or equal to about 100 nm.

The semiconductor nanoparticle may include zinc and selenium.

In the emission layer, a mole ratio of carbon to zinc may be greater than or equal to about 0.3:1 or greater than or equal to about 0.4:1. In the emission layer, the mole ratio of carbon to zinc may be less than or equal to about 1000:1 or less than or equal to about 500:1.

In the emission layer, a mole ratio of carbon to selenium may be greater than or equal to about 0.2:1 or greater than or equal to about 0.5:1. In the emission layer, the mole ratio of carbon to selenium may be less than or equal to about 5000:1 or less than or equal to about 1000:1.

In an embodiment, a method of manufacturing the electroluminescent device includes:
providing one of a first electrode and a second electrode; forming an emission layer on the provided electrode; and providing the other one of the first electrode and the second electrode on the emission layer,
where the forming of the emission layer may include: obtaining a composition for forming the emission layer including a carbon nanoparticle and a semiconductor nanoparticle in an organic solvent; and forming the emission layer by applying the composition for forming the emission layer.

The composition for forming the emission layer may not include an insulating polymer or a monomer thereof.

The carbon nanoparticle may be heat-treated at a temperature of greater than or equal to about 80° C., greater than or equal to about 100° C., or greater than or equal to about 150° C., and less than or equal to about 500° C., or less than or equal to about 300° C. before being added to the organic solvent.

The obtaining of the composition for forming the emission layer may include preparing a dispersion in which the semiconductor nanoparticle, the carbon nanoparticle, or both are dispersed in the organic solvent, and stirring the prepared dispersion. The stirring may include sonicating the composition.

An electronic device (e.g., a display device) according to an embodiment may include the electroluminescent device.

In an embodiment, a display device or an electronic apparatus may include the electroluminescent device.

The display device or an electronic apparatus may include (or may be) an augmented reality (AR) device, a virtual reality (VR) device, a handheld terminal (e.g., device), a monitor, a notebook computer, a television, an electronic display board, a camera, an electronic display component for an automatic vehicle, or an electric car.

According to an embodiment, imbalance that may be caused by charge injection into the emission layer can be effectively suppressed or eliminated. A light emitting device of the embodiment may exhibit improved driving stability and may exhibit extended lifetime characteristics.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a schematic cross-sectional view of an exemplary embodiment of an electroluminescent device.

FIG. 2 is a schematic cross-sectional view of an exemplary embodiment of an electroluminescent device.

FIG. 3 is a schematic cross-sectional view of an exemplary embodiment of an electroluminescent device.

FIG. 4A is a schematic cross-sectional view of a QD LED device according to another non-limiting embodiment.

FIG. 4B is a schematic cross-sectional view of a light emitting device (RGB pixel) according to an embodiment.

FIG. 5 is a schematic cross-sectional view of a light emitting device (RGB pixel) according to an embodiment.

FIG. 6 is a schematic front view of a display panel according to an embodiment.

FIG. 7 is a schematic cross-sectional view of the display panel of FIG. 6 taken along line IV-IV.

FIG. 8A shows electroluminescent properties (current density versus voltage) of the light emitting devices of the Examples and the Comparative Example.

FIG. 8B shows electroluminescent properties (luminance versus voltage) of the light emitting devices of the Examples and the Comparative Example.

FIG. 8C shows electroluminescent properties (voltage versus luminance) of the light emitting devices of the Examples and the Comparative Example.

FIG. 9A is a graph showing the lifetime characteristics of the light emitting devices of the Examples and the Comparative Example.

FIG. 9B shows electroluminescent properties (log scale current density versus voltage) of the light emitting devices of the Examples and the Comparative Example.

FIG. 10A is a scanning electron microscope image of the emission layer of the light emitting device of Example 1.

FIG. 10B is a scanning electron microscope image of the emission layer of the light emitting device of Comparative Example 1.

### DETAILED DESCRIPTION

Advantages and characteristics of this disclosure, and a method for achieving the same, will become evident referring to the following exemplary embodiments together with the drawings attached hereto. However, this invention may, be embodied in many different forms, the embodiments should not be construed as being limited to the embodiments set forth herein. Rather, these embodiments are provided so that this disclosure will be thorough and complete, and will fully convey the scope of the invention to those skilled in the art. Like reference numerals refer to like elements throughout.

In order to clearly explain the present disclosure, parts irrelevant to the description are omitted, and the same reference numerals are assigned to the same or similar elements throughout the specification. In the drawings, the thickness of layers, films, panels, regions, etc., are exaggerated for clarity. And in the drawings, for convenience of description, the thickness of some layers and regions are exaggerated.

Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the specification, the term “in cross-section” refers to a view of a cross-section obtained by cutting the relevant portion generally perpendicularly (e.g., substantially perpendicularly with respect to the bottom surface) and observing laterally it from the side.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

As used herein, values of a work function, a conduction band, or a lowest unoccupied molecular orbital (“LUMO”) (or valence band, or highest occupied molecular orbital (“HOMO”)) energy level is expressed as an absolute value from a vacuum level. In addition, when the work function or the energy level is referred to be “deep,” “high” or “large,” the work function or the energy level has a large absolute value based on “0 electron volts (eV)” of the vacuum level, while when the work function or the energy level is referred to be “shallow,” “low,” or “small,” the work function or energy level has a small absolute value based on “0 eV” of the vacuum level. In an aspect, work function herein refers to a minimum energy required to remove an electron from e.g., a solid metal (e.g., a metal surface) to vacuum (e.g., immediately outside the solid surface).

As used herein, the term “peak emission wavelength” is the wavelength at which a given emission spectrum of the light reaches its maximum.

As used herein, the average (value) may be mean or median. In an embodiment, the average (value) may be a mean value.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and TI, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” includes Group VA and includes nitrogen, phosphorus, arsenic, antimony, and bismuth, but is not limited thereto.

As used herein, “Group VI” includes Group VIA and includes sulfur, selenium, and tellurium, but is not limited thereto.

As used herein, “metal” includes a semi-metal such as Si.

As used herein, a number of carbon atoms in a group or a molecule may be referred to as a subscript (e.g., C₆₋₅₀) or as C6 to C50.

As used herein, when a definition is not otherwise provided, “substituted” refers to replacement of at least one hydrogen of a compound or a group with a corresponding substituent including a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heterolaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (=N(NH₂)), an aldehyde group (—C(═O) H), a carbamoyl group (—C(O)NH₂), a thiol group (—SH), an ester group (—C(═O) OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of one or more hydrogen atoms from an alkane, an alkene, an alkyne, or an arene group. In the hydrocarbon or hydrocarbon group, at least one, methylene may be replaced by an oxide moiety, a carbonyl moiety, an ester moiety, —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group having a carbocyclic aromatic system. When the aryl group includes a plurality of rings, the plurality of rings may be fused to each other. Examples include a phenyl group and a naphthyl group. In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, P, Si, B, Se, Ge, Te, S, or a combination thereof.

As used herein, “heteroaryl” refers to an aromatic system having at least one N, O, P, Si, B, Se, Ge, Te, S, or a combination thereof as a ring forming atom. Examples of heteroaryl groups include a pyridinyl group, a pyrimidinyl group, a pyrazinyl group, a pyridazinyl group, a triazinyl group, a quinolinyl group, and an isoquinolinyl group. When the heteroaryl group includes a plurality of rings, the plurality of rings may be fused to each other. In an embodiment, the heteroaryl group may have 3 to 50 carbon atoms, or 6 to 18 carbon atoms, or 6 to 12 carbon atoms.

As used herein, when a definition is not otherwise provided, “alkoxy” refers to an alkyl group linked to oxygen (e.g., alkyl-O—) for example, a methoxy group, an ethoxy group, or a sec-butyloxy group.

The term “cycloalkyl group” as used herein refers to a monovalent monocyclic saturated hydrocarbon group. Examples thereof include a cyclopropyl group, a cyclobutyl group, a cyclopentyl group, a cyclohexyl group, and a cycloheptyl group. In an embodiment, the cycloalkyl group may have 3 to 50 carbon atoms, or 3 to 18 carbon atoms, or 3 to 12 carbon atoms.

The term “heterocycloalkyl group” as used herein refers to a monovalent monocyclic group including at least one N, O, P, Si, B, Se, Ge, Te, S, or a combination thereof as a ring-forming atom in addition to the carbon atoms that are ring-forming atoms. Examples thereof include a tetrahydrofuranyl group and a tetrahydrothiophenyl group. In an embodiment, the heterocycloalkyl group may have 2 to 50 carbon atoms, or 2 to 18 carbon atoms, or 2 to 12 carbon atoms.

The term “cycloalkenyl group” as used herein refers to a monovalent monocyclic hydrocarbon group that has at least one carbon-carbon double bond in its ring, wherein the molecular structure as a whole is non-aromatic. Examples thereof include a cyclopentenyl group, a cyclohexenyl group, and a cycloheptenyl group. In an embodiment, the cycloalkenyl group may have 3 to 50 carbon atoms, or 3 to 18 carbon atoms, or 3 to 12 carbon atoms.

The term “heterocycloalkenyl group” as used herein refers to a monovalent monocyclic group including at least one N, O, P, Si, B, Se, Ge, Te, S, or a combination thereof as a ring-forming atom, and at least one double bond in its ring. Examples of the heterocycloalkenyl group include a 2,3-dihydrofuranyl group and a 2,3-dihydrothiophenyl group. In an embodiment, the heterocycloalkenyl group may have 2 to 50 carbon atoms, or 2 to 18 carbon atoms, or 2 to 12 carbon atoms.

The term “arylalkyl group” refers to an alkyl group substituted with an aryl group. An example of an arylalkyl group is a benzyl group (i.e., —CH₂-phenyl).

The term “alkylaryl group” refers to an aryl group substituted with an alkyl group. An example of an alkylaryl group is a tolyl group.

As used herein, when a definition is not otherwise provided, “amine” is a compound represented by NR₃, wherein each R is independently hydrogen, a C1-C12 alkyl group, a C7-C20 alkylaryl group, a C7-C20 arylalkyl group, or a C6-C18 aryl group.

As used herein, the expression “not including cadmium (or other harmful heavy metal)” means that a concentration of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or zero. In an embodiment, substantially no amount of cadmium (or other harmful heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

Unless mentioned to the contrary, a numerical range recited herein is inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5%, 3%, or 1% of the stated value.

As used herein, a nanoparticle is a structure having at least one region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about 30 nm. In an embodiment, the nanoparticle may have any suitable shape.

The particle size may be a diameter of the particle or an equivalent diameter calculated by assuming a spherical shape. The particle size can be easily and reproducibly obtained using a known or commercially available image analysis tool (e.g., ImageJ) from photographs of particles obtained by electron microscopy (e.g., scanning electron microscopy or transmission electron microscopy) analysis, according to a manual or the like provided by the manufacturer. The image analysis tool and measurement conditions are not particularly limited. As used herein, a dimension (e.g., size or thickness) of a particle may refer to the dimension (e.g., size or thickness) of a single particle or the average of the dimensions (e.g., size or thickness) of a plurality of particles. The average may be a mean or a median. In an embodiment, the average is a mean.

The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape such as at least two pods, or the like and is not limited thereto. The nanoparticle can be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy thereof by controlling a size of a nanocrystal acting as an emission center.

As used herein, the term “T50” is a time (hours, h) required for the brightness (e.g., luminance) of a given device to decrease to 50% of the initial brightness (100%) as, e.g., when, the given device is started to be driven, e.g., operated, at a predetermined initial brightness (e.g., 146 nit or 650 nit).

As used herein, the term “T90” is a time (h) required for the brightness (e.g., luminance) of a given device to decrease to 90% of the initial brightness (100%) as the given device is started to be driven at a predetermined initial brightness (e.g., 146 nit or 650 nit).

As used herein, the phrase “external quantum efficiency (EQE)” is a ratio of the number of photons emitted from a light-emitting diode (LED) to the number of electrons passing through the device and can be a measurement as to how efficiently a given device converts electrons to photons and allows the photons to escape. The EQE may be determined by the following equation:

$$EQE = ( efficiency of injection ) \times ( ( solid ‐ state ) quantum yield ) \times ( efficiency of extraction )$$

wherein the efficiency of injection is a proportion of electrons passing through the device that are injected into the active region, the quantum yield is a proportion of all electron-hole recombinations in the active region that are radiative and produce photons, and the efficiency of extraction is a proportion of photons generated in the active region that escape from the given device.

As used herein, a maximum EQE is a greatest value of the EQE.

As used herein, a maximum luminance is the highest value of luminance for a given device.

As used herein, the phrase, quantum efficiency, may be used interchangeably with the phrase, quantum yield. In an embodiment, the quantum efficiency may be a relative quantum yield or an absolute quantum yield, for example, which can be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (PL) wavelengths thereof, but are not limited thereto.

As used herein, the term “dispersion” refers to a dispersion in which a dispersed phase is a solid, and a continuous medium includes a liquid or a solid different from the dispersed phase. In an embodiment, the ink composition may be in a form of a dispersion. Herein, the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm to several micrometers (μm) or less, (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm).

A bandgap energy of a semiconductor nanoparticle may vary with a size and a composition of a nanocrystal. For example, as a size of the semiconductor nanoparticle increases, the bandgap energy of the semiconductor nanoparticle may become smaller, e.g., narrower, and the semiconductor nanoparticle may emit light having an increased wavelength. A semiconductor nanocrystal may be used as a light-emitting material in various fields such as in, a display device, an energy device, or a bio light-emitting device.

A semiconductor nanoparticle having electroluminescent properties at a level applicable to practical applications may include a hazardous heavy metals such as cadmium (Cd), lead, mercury, or combinations thereof. It may be desirable to provide a semiconductor nanoparticle that emits light of a desired wavelength while substantially not including the hazardous heavy metals. In addition, from an environmental standpoint, it may also be desirable to provide a light emitting device or a display device having an emission layer (light emitting layer) based on a semiconductor nanoparticle that does not include cadmium, a hazardous heavy metal.

A semiconductor nanoparticle according to an embodiment is environmentally friendly, can emit blue light of a desired wavelength with improved luminous efficiency, and may exhibit improved stability against external environments. An electroluminescent device according to an embodiment includes the semiconductor nanoparticle and is a self-emissive light emitting device configured to emit light of a desired wavelength upon application of voltage, with or without a separate light source. The light emitting device and display device of the embodiment are desirable from an environmental perspective.

In an electroluminescent device including a semiconductor nanoparticle in an emission layer, research is ongoing to apply an inkjet printing method for forming the emission layer. An ink composition containing a semiconductor nanoparticle for application in the inkjet printing may include an organic solvent and a semiconductor nanoparticle. There is a technical demand for an ink composition that is discharged from a print head of an inkjet printing device and deposited onto a desired substrate (e.g., an electrode or a charge auxiliary layer) to form an emission layer with a desired quality. Such an ink composition is applicable to an electroluminescent device or the manufacture thereof.

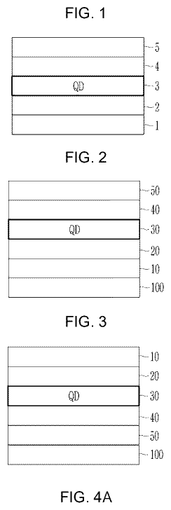

FIG. 1 is a schematic cross-sectional view of an exemplary embodiment of an electroluminescent device. The electroluminescent device of the embodiment of FIG. 1 includes an emission layer 3 including the semiconductor nanoparticle. The emission layer further includes carbon nanoparticles. The electroluminescent device of an embodiment may further include a first electrode 1 and a second electrode 5 that are spaced apart (e.g., facing each other). The emission layer 3 may be disposed between the first electrode and the second electrode. The electroluminescent device may further include a hole auxiliary layer, an electron auxiliary layer, or both. The emission layer 3 may be disposed between the hole auxiliary layer and the electron auxiliary layer (e.g., electron transport layer).

The hole auxiliary layer may be disposed between the first electrode (e.g., an anode) and the emission layer. The electron auxiliary layer may be disposed between the second electrode (e.g., a cathode) and the emission layer (see FIG. 1). The semiconductor nanoparticle or the emission layer may include or may not include cadmium, mercury, lead, or a combination thereof. The first electrode may include an anode, and the second electrode may include a cathode. Alternatively, the first electrode may include a cathode, and the second electrode may include an anode. The electroluminescent device may further include a hole auxiliary layer 2 between the emission layer 3 and the first electrode 1. The electroluminescent device may further include an electron auxiliary layer 4 between the emission layer 3 and the second electrode 5.

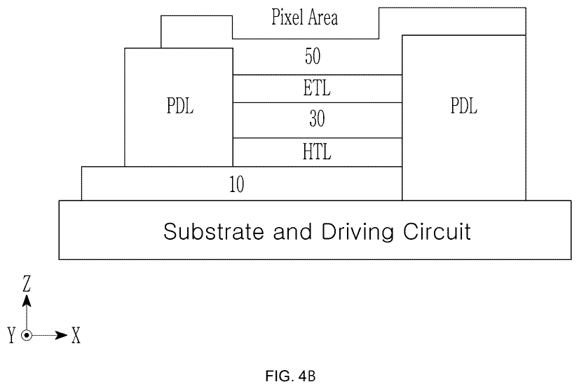

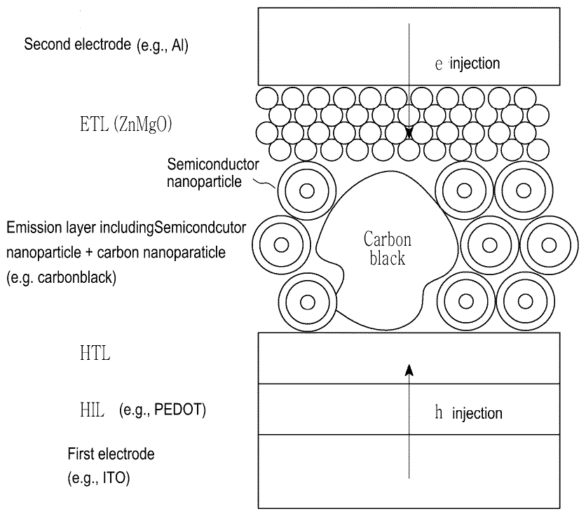

In the electroluminescent device, the first electrode or the second electrode may be disposed on a (transparent) substrate 100. The transparent substrate may be a light extraction surface (see FIG. 2 and FIG. 3).

Referring to FIGS. 2 and 3, in an electroluminescent device of an embodiment, an emission layer 30 may be disposed between a first electrode (e.g., anode) 10 and a second electrode (e.g., cathode) 50. The cathode 50 may include an electron injection conductor. The anode 10 may include a hole injection conductor. A work function of each of the electron or hole injection conductors included in the cathode and the anode may be appropriately adjusted and are not particularly limited. For example, the cathode may have a small work function and the anode may have a relatively large work function, or vice versa.

The electron or hole injection conductors may include a metal-based (i.e., metal-containing) material (e.g., a metal, a metal compound, an alloy, or a combination thereof) such as aluminum, magnesium, tungsten, nickel, cobalt, platinum, palladium, calcium, LiF, etc.; a metal oxide such as gallium indium oxide or indium tin oxide (ITO); or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The first electrode, the second electrode, or a combination thereof may each be a patterned electrode.

The first electrode, the second electrode, or a combination thereof may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate may have a transmittance of greater than or equal to about 50%, greater than or equal to about 60%, greater than or equal to about 70%, greater than or equal to about 80%, or greater than or equal to about 90% for light emitted from semiconductor nanoparticles that are described herein. The substrate 100 may include a region for a blue pixel, a region for a red pixel, a region for a green pixel, or a combination thereof. In an embodiment, a thin film (e.g., film) transistor may be disposed in each region of the substrate, but it is not limited thereto. In an embodiment, a source electrode or a drain electrode of the thin film transistor may be electrically connected to the first electrode or the second electrode.

A light-transmitting electrode may be disposed on a (e.g., insulating) transparent substrate. The substrate may be rigid or flexible. The substrate may include (e.g., maybe) a plastic, a glass, a metal, or a combination thereof. The light-transmitting electrode may have a light transmittance of greater than or equal to about 50%, greater than or equal to about 60%, greater than or equal to about 70%, greater than or equal to about 80%, or greater than or equal to about 90%, for example, in a range of about 80% to about 100%, about 85% to about 95%, or a combination thereof.

The light-transmitting electrode may include, but is not limited to, a transparent conductive material such as an indium tin oxide (ITO), indium zinc oxide (IZO), gallium indium tin oxide, zinc indium tin oxide, titanium nitride, polyaniline, or LiF/Mg:Ag; a single layer or a plurality of layers of a thin metal film; or a combination thereof. The first electrode, the second electrode, or a combination thereof may include aluminum (Al), a lithium-aluminum (Li:Al) alloy, a magnesium-silver (Mg:Ag) alloy, or a lithium fluoride-aluminum (LiF:Al) composite. In the case of an alloy electrode, a ratio between each material may be appropriately adjusted and may be, for example, in a range of about 1:0.1 to about 1:10, about 1:0.2 to about 1:5, about 1:0.3 to about 1:3, or a combination thereof.

In an embodiment, the first electrode or the second electrode may be a multilayer electrode. In an embodiment, the first electrode (or anode) may be a multilayer electrode including greater than or equal to about two layers, greater than or equal to about three layers, and less than or equal to about ten layers or less than or equal to about five layers of electrode materials. In an embodiment, the second electrode (or cathode) may be a multilayer electrode including greater than or equal to about two layers, greater than or equal to about three layers, and less than or equal to about ten layers or less than or equal to about five layers of electrode materials.

The multilayer electrode may include, for example, a transparent conductive material such as indium tin oxide, an opaque conductive material (or reflective electrode material) such as aluminum, or a combination thereof. In an embodiment, the electrode (e.g., the anode or cathode) may have a structure in which an opaque conductive material (or reflective electrode material layer) is disposed between transparent conductive materials (e.g., transparent conductive material layers). In an embodiment, the electrode (anode or cathode) may have a structure in which a transparent conductive material (e.g., a transparent conductive material layer) is disposed between opaque conductive materials (or reflective electrode materials).

When a voltage is applied between the first electrode and the second electrode, the emission layer may emit light upward and downward under an electric field, and light proceeding toward the reflective electrode may be reflected and emitted in the opposite direction. In an embodiment, the light may be emitted toward the cathode side. In another embodiment, the light may be emitted toward the anode side.

The thickness of an electrode (the first electrode and/or the second electrode) is not particularly limited and may be appropriately selected in consideration of device efficiency. For example, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 micrometers (μm), less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, or less than or equal to about 60 nm.

The method of forming the electrode is not particularly limited, and can be appropriately selected taking into consideration an electrode material. In one implementation, the electrode can be formed by deposition, coating, or a combination thereof, but is not limited thereto.

The emission layer 3, or 30, may be disposed between the first electrode 1 and the second electrode 5 (e.g., the anode 10 and the cathode 50). The emission layer may include a semiconductor nanoparticle (e.g., a plurality of semiconductor nanoparticles) such as a blue light-emitting nanoparticle, a red light-emitting nanoparticle, or a green light-emitting nanoparticle. The emission layer may include one or more (e.g., 2 or more, or 3 or more, and 10 or less) monolayers of the semiconductor nanoparticle.

The emission layer or a semiconductor nanoparticle included therein is configured to emit a first light having an emission peak (e.g., single emission peak), for example, having a predetermined peak emission wavelength, by applying a predetermined voltage between the first electrode and the second electrode.

The first light may be a blue light. The peak emission wavelength of the first light may be within a blue wavelength region. The peak emission wavelength of the first light or the blue wavelength region may be greater than or equal to about 440 nm, greater than or equal to about 445 nm, greater than or equal to about 450 nm, or greater than or equal to about 445 nm. The blue wavelength region may be less than or equal to about 480 nm, less than or equal to about 475 nm, less than or equal to about 470 nm, less than or equal to about 465 nm, less than or equal to about 460 nm, or less than or equal to about 457 nm.

The first light may be a green light. The peak emission wavelength of the first light may be within a green wavelength region. The peak emission wavelength of the first light or the green wavelength region may be greater than or equal to about 500 nm, greater than or equal to about 505 nm, greater than or equal to about 510 nm, greater than or equal to about 515 nm, or greater than or equal to about 520 nm. The green wavelength region may be less than or equal to about 580 nm, less than or equal to about 560 nm, less than or equal to about 555 nm, less than or equal to about 550 nm, less than or equal to about 545 nm, or less than or equal to about 540 nm.

The first light may be a red light. The peak emission wavelength of the first light may be within a red wavelength region. The peak emission wavelength of the first light or the red wavelength region may be greater than or equal to about 600 nm, greater than or equal to about 605 nm, greater than or equal to about 610 nm, greater than or equal to about 615 nm, greater than or equal to about 620 nm, or greater than or equal to about 625 nm. The red wavelength region may be less than or equal to about 680 nm, less than or equal to about 675 nm, less than or equal to about 670 nm, less than or equal to about 665 nm, less than or equal to about 660 nm, less than or equal to about 655 nm, less than or equal to about 650 nm, less than or equal to about 645 nm, less than or equal to about 640 nm, or less than or equal to about 635 nm.

The peak emission or the emission peak at which the peak emission is located may have a full width at half maximum (FWHM) that is greater than or equal to about 5 nm, greater than or equal to about 10 nm, greater than or equal to about 15 nm, or greater than or equal to about 20 nm. The peak emission or the emission peak at which the peak emission is located may have the FWHM that is less than or equal to about 50 nm, less than or equal to about 45 nm, less than or equal to about 40 nm, less than or equal to about 35 nm, less than or equal to about 30 nm, or less than or equal to about 25 nm.

The first light may not be mixed light (for example, mixed light of green light and red light).

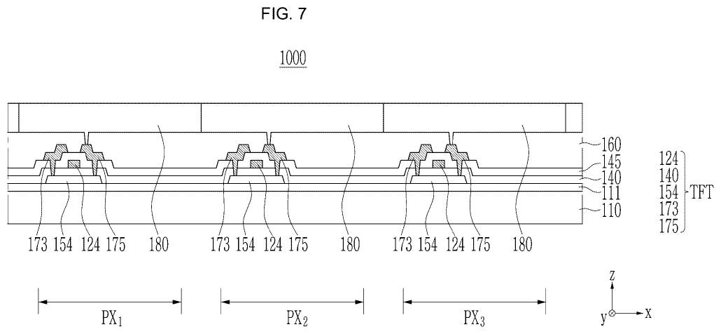

The emission layer may be patterned. In an embodiment, the patterned emission layer may include a blue emission layer (e.g., disposed in a blue subpixel of a display device described later), a red emission layer (e.g., disposed in a red subpixel of the display device described later), a green emission layer (e.g., disposed in a green subpixel of the display device described later), or a combination thereof. Each emission layer may be separated (e.g., optically) from an adjacent emission layer by a partition wall. In an embodiment, a partition wall or a bank such as a black matrix or a pixel defining layer (PDL) may be disposed between the red emission layer(s), green emission layer(s), and blue emission layer(s) (see FIG. 4A and FIG. 7). In a non-limiting embodiment, the red emission layer, the green emission layer, and the blue emission layer may each be substantially optically isolated.

In the emission layer of an embodiment, the semiconductor nanoparticle may exhibit a zinc blende crystal structure, a perovskite crystal structure, or a combination thereof.

In an embodiment, the emission layer 3, 30, or the semiconductor nanoparticle may not include cadmium. In an embodiment, the emission layer 3, 30, or the semiconductor nanoparticle may not include mercury, lead, or a combination thereof. The semiconductor nanoparticle may include or may not include copper, manganese, or a combination thereof.

In an embodiment, the semiconductor nanoparticle may have a core-shell structure. In an embodiment, the semiconductor nanoparticle or the core-shell structure may include a core including a first semiconductor nanocrystal and a shell disposed on the core and including a second semiconductor nanocrystal having a composition different from that of the first semiconductor nanocrystal.

The semiconductor nanoparticle (or the first semiconductor nanocrystal, the second semiconductor nanocrystal, or a combination thereof) may include a Group II-VI compound, a Group III-V compound, a Group IV-VI compound, a Group IV element or compound, a Group I-III-VI compound, a Group II-III-VI compound, a Group I-II-IV-VI compound, a metal halide perovskite compound, a transition metal chalcogenide perovskite compound, or a combination thereof. The semiconductor nanoparticle may include a silver indium gallium sulfide, an indium phosphide, an indium zinc phosphide, a zinc chalcogenide, or a combination thereof. In an embodiment, the zinc chalcogenide may be a class of semiconducting material for example having a general formula ZnX, where X represents a chalcogen element (sulfur, selenium, tellurium, or a combination thereof). A mole ratio between the element can be adjusted.

The Group II-VI compound may include a binary element compound such as ZnS, ZnSe, ZnTe, ZnO, HgS, HgSe, HgTe, MgSe, MgS, or a combination thereof; a ternary element compound such as ZnSeS, ZnSeTe, ZnSTe, HgSeS, HgSeTe, HgSTe, HgZnS, HgZnSe, HgZnTe, MgZnSe, MgZnS, or a combination thereof; a quaternary element compound such as HgZnTeS, HgZnSeS, HgZnSeTe, HgZnSTe, or a combination thereof; or a combination thereof. The Group II-VI compound may further include a Group III metal.

The Group III-V compound may include a binary element compound such as GaN, GaP, GaAs, GaSb, AlN, AlP, AlAs, AlSb, InN, InP, InAs, InSb, or a combination thereof; a ternary element compound such as GaNP, GaNAs, GaNSb, GaPAs, GaPSb, AlNP, AlNAs, AlNSb, AlPAs, AlPSb, InNP, InNAs, InNSb, InPAs, InPSb, or a combination thereof; a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof. The Group III-V compound may further include a Group II metal (e.g., InZnP).

The Group IV-VI compound may include a binary element compound such as SnS, SnSe, SnTe, PbS, PbSe, PbTe, or a combination thereof; a ternary element compound such as SnSeS, SnSeTe, SnSTe, PbSeS, PbSeTe, PbSTe, SnPbS, SnPbSe, SnPbTe, or a combination thereof; a quaternary element compound such as SnPbSSe, SnPbSeTe, SnPbSTe, or a combination thereof; or a combination thereof.

Examples of the Group I-III-VI compound may include CuInSe₂, CuInS₂, CuInGaSe, and CuInGaS, but are not limited thereto. Examples of the Group I-III-VI compound may include a ternary element compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂ or a combination thereof; a quaternary element compound such as AgInGaS₂, AgInGaSe₂; or a combination thereof.

Examples of the Group I-II-IV-VI compound may be CuZnSnSe, and CuZnSnS, but are not limited thereto.

The Group IV element or compound may include a single element such as Si, Ge, or a combination thereof; a binary element compound such as SiC, SiGe, or a combination thereof; or a combination thereof.

The metal halide perovskite compound may be represented by Chemical Formula 1:

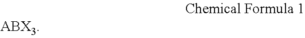

In Chemical Formula 1, A is an alkali metal, the NR₄⁺, [CH(NH₂)₂]⁺, an organic guanidium, or a combination thereof, B is a transition metal, a group IVA metal, an alkaline earth metal, a rare earth metal, or a combination thereof. X is F, Cl, Br, I, or a combination thereof, R is the same or different, and is hydrogen or a C1-C10 alkyl group, such as a methyl group.

The alkali metal may include Rb, Cs, or a combination thereof. The IVA group metal may include Ge, Si, Sn, Pb, or a combination thereof.

The metal halide or the metal halide perovskite compound may be CsPbCl₃, CsPbBr₃, CsPbI₃, CsPb(Cl,I)₃, CsPb(Br,I)₃, CsPb(Br,Cl)₃, or a combination thereof. As used herein, “(Cl,I), (Br,I), or (Br,Cl)” means that the compound includes two kinds of halogens (i.e., Cl and I, Br and I, or Br and Cl), and in the case where the compound includes two kinds of halogens (X1, X2), the molar ratio of both is not particularly limited.

The transition metal chalcogenide or the transition metal chalcogenide perovskite compound may include a compound represented by Chemical Formula 2:

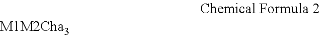

In Chemical Formula 2, M1 is Ca, Sr, Ba, or a combination thereof,
M2 is Ti, Zr, Hf, or a combination thereof, and
Cha is S, Se, Te, or a combination thereof.

The transition metal chalcogenide may include BaZrS₃, SrZrS₃, CaZrS₃, SrTiS₃, BaTiS₃, BaZr₁₋ₓTixS₃ (where x is greater than 0 and less than or equal to about 0.5), BaZrSe₃, SrZrSe₃, CaZrSe₃, SrTiSe₃, BaTiSe₃, BaZr₁₋ₓTiₓSe₃ (where x is greater than 0 and less than or equal to about 0.5), BaZrTe₃, SrZrTe₃, CaZrTe₃, SrTiTe₃, BaTiTe₃, BaZr₁₋ₓTiₓTe₃ (where x is greater than 0 and less than or equal to about 0.5), or a combination thereof.

The semiconductor nanoparticles including the metal halide compound or the transition metal chalcogenide may include, for example, a perovskite crystal structure confirmed by an X-ray diffraction spectrum.

Each element included in a multi-element compound such as a binary element compound, a ternary element compound, or a quaternary element compound may be present in the particle at a uniform concentration or at a non-uniform concentration. For example, the chemical formula described above means the types of elements included in the compound, and the ratio among the elements in the compound may be different. For example, the chemical formula “AgInGaS₂” may include AgInₓGa₁₋ₓS₂ (x is a real number of greater than 0 to less than 1), but is not limited thereto.

In an embodiment, the first semiconductor nanocrystal may include a metal including indium, zinc, or a combination thereof, and a non-metal including phosphorus, selenium, tellurium, sulfur, or a combination thereof. In an embodiment, the second semiconductor nanocrystal may include a metal including indium, zinc, or a combination thereof, and a non-metal element including phosphorus, selenium, tellurium, sulfur, or a combination thereof.

In an embodiment, the first semiconductor nanocrystal may include AgInGaS, AgGaS, InP, InZnP, ZnSe, ZnSeS, ZnSeTe, or a combination thereof; and/or the second semiconductor nanocrystal may include ZnSe, ZnSeS, ZnS, ZnTeSe, or a combination thereof. In an embodiment, the shell may include zinc, sulfur, and optionally selenium for example in the outermost layer.

In an embodiment, the semiconductor nanoparticle may emit blue or green light and may include a core including ZnSeTe, ZnSe, or a combination thereof, and a shell including a zinc chalcogenide (e.g., ZnS, ZnSe, ZnSeS, or a combination thereof). An amount of sulfur in the shell may increase or decrease in a radial direction (from the core toward the surface), e.g., the amount of sulfur may have a concentration gradient wherein the concentration of sulfur varies radially (e.g., decreases or increases in a direction toward the core).

In an embodiment, the semiconductor nanoparticle may emit red or green light, the core may include InP, InZnP, or a combination thereof, and the shell may include a Group II metal including zinc and a non-metal including sulfur, selenium, or a combination thereof.

In an embodiment, the semiconductor nanoparticle may have a core-shell structure, and on the interface between the core and the shell, an alloyed interlayer may be present or may not be present. The alloyed interlayer layer may include a homogeneous alloy or may have a concentration gradient. The gradient alloy may have a concentration gradient wherein the concentration of an element of the shell varies radially (e.g., decreases or increases in a direction toward the core). In an embodiment, the shell may have a composition that varies in a radial direction. In an embodiment, the shell may be a multilayered shell including two or more layers. In a multilayered shell, adjacent two layers may have different compositions from each other. In a multilayered shell, a, e.g., at least one, layer may independently include a semiconductor nanocrystal having a single composition. In a multilayered shell, a, e.g., at least one, layer may independently have an alloyed semiconductor nanocrystal. In a multilayered shell, a, e.g., at least one, layer may have a concentration gradient that varies radially in terms of a composition of a semiconductor nanocrystal.

In an embodiment, in the semiconductor nanoparticle having a core-shell structure, a shell material may have a bandgap energy that is greater than that of the core. The materials of the shell may have a bandgap energy that is less than that of the core. In the case of a multilayered shell, the bandgap energy of the outermost layer material of the shell may be greater than the bandgap energies of the core and the inner layer material of the shell (layers that are closer to the core). In the case of a multilayered shell, a semiconductor nanocrystal of each layer is selected to have an appropriate bandgap, thereby effectively exhibiting a quantum confinement effect.

The semiconductor nanoparticle according to an embodiment may include, for example, an organic ligand which is bonded or coordinated to a surface thereof.

An absorption or emission wavelength of the semiconductor nanoparticle may be controlled by adjusting the compositions, the particle size, or a combination thereof, of the semiconductor nanoparticle. The semiconductor nanoparticle included in the emission layer 3, or 30, may emit light of a desired color. The semiconductor nanoparticle may include a blue light-emitting semiconductor nanoparticle, a green light-emitting semiconductor nanoparticle, or a red light-emitting semiconductor nanoparticle. In an embodiment, the emission layer may be configured to emit blue light, green light, or red light, and wavelengths of blue light, green light, and red light are as described herein.

In an embodiment, the semiconductor nanoparticle, the emission layer, or the electroluminescent device may exhibit a luminescent spectrum (e.g., photo- or electro-luminescent spectrum) with a relatively narrow full width at half maximum. In an embodiment, in the photo- or electro-luminescent spectrum, the semiconductor nanoparticle, the emission layer, or the electroluminescent device may exhibit a full width at half maximum of less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum (FWHM) may be greater than or equal to about 1 nm, greater than or equal to about 5 nm, greater than or equal to about 10 nm, greater than or equal to about 15 nm, or greater than or equal to about 20 nm.

The semiconductor nanoparticle may exhibit a quantum efficiency (or quantum yield) of greater than or equal to about 10%, for example, greater than or equal to about 30%, greater than or equal to about 50%, greater than or equal to about 60%, greater than or equal to about 70%, greater than or equal to about 80%, greater than or equal to about 90%, or about 100%.

The semiconductor nanoparticle may have a size (or an average size, hereinafter, can be simply referred to as “size”) of greater than or equal to about 1 nm and less than or equal to about 100 nm. In an embodiment, the semiconductor nanoparticle may have a size of from about 1 nm to about 50 nm, for example, from about 2 nm (or about 3 nm) to about 35 nm. In an embodiment, the size of the semiconductor nanoparticle may be greater than or equal to about 1 nm, greater than or equal to about 2 nm, greater than or equal to about 3 nm, greater than or equal to about 4 nm, or greater than or equal to about 5 nm. In an embodiment, the size of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, or less than or equal to about 15 nm.

A shape of the semiconductor nanoparticle or the semiconductor nanostructure is not particularly limited. For example, the shape of the semiconductor nanoparticle may include, but is not limited to, a sphere, a polyhedron, a pyramid, a multi-pod shape, a hexahedron, a cube, a cuboid, a nanotube, a nanorod, a nanowire, or a nanosheet.

The semiconductor nanoparticle may be prepared using an appropriate method. The semiconductor nanoparticle may be prepared for example by a chemical wet method wherein a nanocrystal particle may grow by a reaction between precursors in a reaction system including an organic solvent and an organic ligand. The organic ligand or the organic solvent may coordinate (with or to) a surface of the semiconductor nanocrystal to control the growth thereof.

In an embodiment, for example, the method for preparing the semiconductor nanoparticle having a core/shell structure may include obtaining the core; preparing a first shell precursor solution including a first shell precursor containing a metal (e.g., zinc) and optionally an organic ligand; preparing a second shell precursor containing a non-metal element (e.g., sulfur, selenium, or a combination thereof); and heating the first shell precursor solution to a reaction temperature (e.g., greater than or equal to about 180° C., greater than or equal to about 200° C., greater than or equal to about 240° C., or greater than or equal to about 280° C. to less than or equal to about 360° C., less than or equal to about 340° C., or less than or equal to about 320° C.) and adding the core and the second shell precursor (e.g., once or more, or twice or more) to form a shell of a second semiconductor nanocrystal on the first semiconductor nanocrystal core. The method may further include separating the core from a reaction system used for its preparation and dispersing it in an organic solvent to prepare a core dispersion.

In an embodiment, for a shell formation, a solvent and optionally a ligand compound may be heated (or vacuum-treated) under vacuum to a predetermined temperature (e.g., 100° C. or higher), and thereafter, may be heated to a predetermined temperature (e.g., 120° C. or higher) after introducing nitrogen (inert atmosphere) into the reaction flask. Subsequently, the core may be added to the flask, and the shell precursors are sequentially or simultaneously added, and the reaction flask may be heated at a predetermined reaction temperature. One or more shell precursors may be sequentially introduced in different proportions of the mixture during the reaction time to provide a desired compositional gradient of the shell layer.

In the semiconductor nanoparticle of an embodiment, the core may be prepared by an appropriate method.

The organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., triocty phosphine) substituted with at least one (e.g., 1, 2, or 3) C6 to C22 alkyl group, a phosphine oxide (e.g. trioctylphosphine oxide) substituted with a (e.g., 1, 2, or 3) C6 to C22 alkyl group, a C12 to C22 aromatic ether such as phenyl ether or benzyl ether, or a combination thereof.

The organic ligand may coordinate the surfaces of the prepared semiconductor nanoparticles and allow the semiconductor nanoparticles to be well dispersed in the solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, (wherein R and R′ independently include substituted or unsubstituted C1 or more, C6 or more, or C10 or more and C40 or less, C35 or less, or C25 or less aliphatic hydrocarbon group, or substituted or unsubstituted C6 to C40 aromatic hydrocarbon group, or a combination thereof), or a combination thereof. The ligands may be used alone or as a mixture of two or more compounds.

The semiconductor nanoparticle may be recovered by a process of pouring a non-solvent into a mixture including the semiconductor nanoparticle and subjecting the mixture to a centrifugation in order to remove excess organic substance that is not coordinated on the surface from them. For example, in an embodiment, after completing the reaction (for the formation of the core or for the formation of the shell), a non-solvent may be added to a reaction mixture and the semiconductor nanoparticle coordinated with the ligand compound may be separated therefrom. The non-solvent may be a polar solvent that is miscible with the solvent used in the core formation reactions, shell formation reaction, or a combination thereof, and is not capable of dispersing the prepared semiconductor nanoparticles. The non-solvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing non-solvents, or a combination thereof.

The semiconductor nanoparticles may be separated through centrifugation, sedimentation, or chromatography. The separated semiconductor nanoparticles may be washed with a washing solvent, if desired. The washing solvent has no particular limit and may have a similar solubility parameter to that of the ligand and may, for example, include hexane, heptane, octane, chloroform, toluene, benzene, and the like.

The semiconductor nanoparticles of an embodiment may be non-dispersible or insoluble in water, the aforementioned non-solvent, or a combination thereof. The semiconductor nanoparticles of an embodiment may be dispersed in the aforementioned organic solvent. In an embodiment, the aforementioned semiconductor nanoparticles may be dispersed in a substituted or unsubstituted C6 to C40 aliphatic hydrocarbon, a substituted or unsubstituted C6 to C40 aromatic hydrocarbon, or a combination thereof.

A semiconductor nanoparticle disposed in the emission layer positioned between a pair of electrodes may function as a light-emitting center. Compared to organic emitters, an inorganic semiconductor nanoparticle (e.g., a quantum dot) may emit light with a relatively narrow emission spectrum at a relatively high efficiency. In such electroluminescent devices, an imbalance in the injection of charges (e.g., electrons and holes) may occur around the emission layer, which functions as a resistive layer. Without wishing to be bound by any theory, such charge injection imbalance may negatively affect the performance and/or lifespan of the device and may also lead to degradation in the driving stability of the device.

An environmentally friendly, Cd-free, blue light-emitting semiconductor nanoparticle may optionally include a ZnSe-based core including Te, and a ZnS-containing shell. The ZnS outermost shell, which has a wider energy bandgap than the energy bandgap of the light-emitting core (e.g., including a ZnSeTe), may contribute to achieving improved emission efficiency of the semiconductor nanoparticle. In such environmentally friendly semiconductor nanoparticles, achieving a balance between the injected electrons and holes may be an even more challenging task. This imbalance between electrons and holes may affect the operational voltage stability, device lifetime characteristics, and electroluminescent performance of the entire device.

The present inventors have surprisingly found that the emission layer including semiconductor nanoparticles and disposed between electrodes may exhibit improved lifetime characteristics and electroluminescent properties in the final device by further including (e.g., conductive) carbon nanoparticles (e.g., carbon black or the like) or an assembly thereof (see FIG. 4B). Different from the semiconductor nanoparticles in the emission layer, the carbon nanoparticles in the emission layer may be non-luminous (does not exhibit photoluminescence). Without wishing to be bound by any theory, it is believed that when included in the emission layer, the carbon nanoparticle may contribute to resolving charge imbalance or excessive charge issues resulting therefrom substantially without generating substantial leakage current, thereby improving the driving stability and lifetime characteristics of the device as a whole. In a device according to an embodiment, the emission layer may include a carbon nanoparticle together with the cadmium-free semiconductor nanoparticle described herein, and as a result, technical issues caused by excessive charge injection (e.g., electron injection) may be resolved. In an electroluminescent device according to an embodiment, the use of an emission layer including the carbon nanoparticle and the semiconductor nanoparticle may shift the operating voltage of the device to a lower voltage, and for example, exhibit improved emission efficiency (e.g., external quantum efficiency) even in a relatively high luminance range. In addition, voltage increase during a sweep measurement experiment from low luminance to high luminance may also be suppressed. An electroluminescent device according to an embodiment may exhibit an extended lifetime by including such an emission layer.

Accordingly, in an embodiment of the light emitting device, the emission layer further includes a carbon nanoparticle. The emission layer may include a plurality of the carbon nanoparticles. The emission layer may include an assembly of a plurality of the carbon nanoparticles that are adjacent to one another (see carbon black in FIG. 4B). Referring to FIG. 4B, “carbon black” may be a single carbon nanoparticle or an assembly thereof. The assembly may include an aggregate, an agglomerate, or a combination thereof. The carbon nanoparticle may include a carbon black, a graphite nanopowder, a graphene nanoparticle, a graphene oxide nanoparticle, or a combination thereof. The carbon black, the graphite nanopowder, and the graphene nanoparticle are commercially available or may be prepared by any known method. The carbon nanoparticle may be a material having a relatively high surface area to volume ratio.

In an embodiment, the carbon nanoparticle may be (e.g., electrically conductive) carbon black. The carbon black may be produced by the incomplete combustion of various materials (e.g., coal tar, plant-derived materials, naphthalene, anthracene, acetylene gas, FCC tar, creosote, or various petroleum products). The carbon black may include para-crystalline carbon, amorphous carbon, or a combination thereof. In an embodiment, the carbon black may include acetylene black, Ketjen black, furnace black, or a combination thereof, but is not limited thereto.

The carbon nanoparticle may have at least one dimension (e.g., particle diameter or thickness) in the nanoscale. The carbon nanoparticle may be a sheet-like or plate-like material (i.e., flat, thin materials with a large surface area relative to its thickness) such as graphene or graphene oxide, in which case the thickness may be in the nanoscale.

The carbon nanoparticle may have an (average) thickness or an (average) size, (for example, an (average) particle diameter) that is greater than or equal to about 1 nm, greater than or equal to about 2 nm, greater than or equal to about 3 nm, greater than or equal to about 5 nm, greater than or equal to about 7 nm, greater than or equal to about 9 nm, greater than or equal to about 10 nm, greater than or equal to about 11 nm, greater than or equal to about 13 nm, greater than or equal to about 15 nm, greater than or equal to about 17 nm, greater than or equal to about 19 nm, greater than or equal to about 20 nm, greater than or equal to about 21 nm, greater than or equal to about 23 nm, greater than or equal to about 25 nm, greater than or equal to about 27 nm, greater than or equal to about 29 nm, greater than or equal to about 30 nm, greater than or equal to about 31 nm, greater than or equal to about 33 nm, greater than or equal to about 35 nm, greater than or equal to about 37 nm, greater than or equal to about 39 nm, greater than or equal to about 40 nm, greater than or equal to about 41 nm, greater than or equal to about 43 nm, greater than or equal to about 45 nm, greater than or equal to about 47 nm, or greater than or equal to about 49 nm. The (average) thickness or the (average) size may be less than or equal to about 100 nm, less than or equal to about 70 nm, less than or equal to about 60 nm, less than or equal to about 50 nm, less than or equal to about 48 nm, less than or equal to about 46 nm, less than or equal to about 45 nm, less than or equal to about 44 nm, less than or equal to about 42 nm, less than or equal to about 40 nm, less than or equal to about 38 nm, less than or equal to about 36 nm, less than or equal to about 34 nm, less than or equal to about 32 nm, less than or equal to about 28 nm, less than or equal to about 24 nm, less than or equal to about 22 nm, less than or equal to about 18 nm, or less than or equal to about 14 nm.

The carbon nanoparticle may form an assembly. The assembly may include an aggregate, an agglomerate, or a combination thereof. A dimension (e.g., a particle size or an lateral size) of the assembly may be greater than or equal to about 30 nm, greater than or equal to about 50 nm, greater than or equal to about 70 nm, greater than or equal to about 90 nm, greater than or equal to about 100 nm, greater than or equal to about 120 nm, greater than or equal to about 140 nm, greater than or equal to about 160 nm, greater than or equal to about 180 nm, greater than or equal to about 200 nm, greater than or equal to about 220 nm, greater than or equal to about 240 nm, greater than or equal to about 260 nm, greater than or equal to about 280 nm, or greater than or equal to about 300 nm. The dimension (e.g., a particle size or an lateral size) of the assembly may be less than or equal to about 1000 nm, less than or equal to about 900 nm, less than or equal to about 800 nm, less than or equal to about 600 nm, less than or equal to about 500 nm, less than or equal to about 400 nm, less than or equal to about 300 nm, less than or equal to about 200 nm, or less than or equal to about 120 nm.

In an embodiment, the dimension (e.g., a particle size or an lateral size) of the assembly may be in the micron scale, for example, greater than or equal to about 0.1 μm, greater than or equal to about 0.3 μm, greater than or equal to about 0.5 μm, greater than or equal to about 0.7 μm, greater than or equal to about 0.9 μm, greater than or equal to about 1 micrometer (μm), greater than or equal to about 1.1 μm, greater than or equal to about 1.3 μm, greater than or equal to about 1.5 μm, greater than or equal to about 1.7 μm, greater than or equal to about 1.9 μm, greater than or equal to about 2 μm, or greater than or equal to about 2.5 μm. The dimension of the assembly may be less than or equal to about 10 μm, less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, or less than or equal to about 1 μm.

The assembly may be separated into aggregates or carbon nanoparticles under relatively high levels of shear force. In an embodiment, carbon black may refer to a group of black, small-sized, finely divided amorphous carbon or paracrystalline carbon particles. These carbon particles may grow together to form assemblies having different sizes and shapes.

The carbon nanoparticle may include crystalline carbon, amorphous carbon, paracrystalline carbon, or a combination thereof. The carbon nanoparticle may be a graphite nanoparticle, a graphene nanoparticle, or a combination thereof. The graphite nanoparticle may include stacked graphene sheets and may exhibit electrical conductivity. The graphite nanoparticle may include a stacked structure having carbon particles arranged in a hexagonal lattice and may be crystalline carbon. In an embodiment, the carbon nanoparticle may be carbon black. The carbon black may include amorphous carbon and/or paracrystalline carbon. The carbon nanoparticle may be a non-emissive particle.

The carbon nanoparticle may have an oil absorption, for example, dibutyl phthalate (DBP) absorption, that is greater than or equal to about 10 cubic centimeters (cc)/100 g, greater than or equal to about 15 cc/100 g, greater than or equal to about 20 cc/100 g, greater than or equal to about 25 cc/100 g, greater than or equal to about 30 cc/100 g, greater than or equal to about 35 cc/100 g, greater than or equal to about 40 cc/100 g, greater than or equal to about 45 cc/100 g, greater than or equal to about 50 cc/100 g, greater than or equal to about 55 cc/100 g, greater than or equal to about 60 cc/100 g, greater than or equal to about 65 cc/100 g, greater than or equal to about 70 cc/100 g, greater than or equal to about 75 cc/100 g, or greater than or equal to about 80 cc/100 g. The oil absorption, for example, DBP absorption may be less than or equal to about 2000 cc/100 g, less than or equal to about 1800 cc/100 g, less than or equal to about 1500 cc/100 g, less than or equal to about 1200 cc/100 g, less than or equal to about 1000 cc/100 g, less than or equal to about 800 cc/100 g, less than or equal to about 500 cc/100 g, less than or equal to about 400 cc/100 g, less than or equal to about 300 cc/100 g, less than or equal to about 250 cc/100 g, less than or equal to about 200 cc/100 g, less than or equal to about 150 cc/100 g, less than or equal to about 120 cc/100 g, or less than or equal to about 100 cc/100 g.

The carbon nanoparticle may have a relatively high specific surface area. The specific surface area of the carbon nanoparticle or the carbon black (e.g., based on Brunauer-Emmett-Teller (BET) method) may be greater than or equal to about 2 m²/g, greater than or equal to about 3 m²/g, greater than or equal to about 5 m²/g, greater than or equal to about 7 m²/g, greater than or equal to about 9 m²/g, greater than or equal to about 11 m²/g, greater than or equal to about 13 m²/g, greater than or equal to about 15 m²/g, greater than or equal to about 18 m²/g, greater than or equal to about 20 m²/g, greater than or equal to about 30 m²/g, greater than or equal to about 40 m²/g, greater than or equal to about 50 m²/g, greater than or equal to about 60 m²/g, greater than or equal to about 70 m²/g, greater than or equal to about 75 m²/g, greater than or equal to about 80 m²/g, greater than or equal to about 85 m²/g, greater than or equal to about 90 m²/g, greater than or equal to about 95 m²/g, or greater than or equal to about 100 m²/g. The specific surface area of the carbon nanoparticle or the carbon black may be less than or equal to about 1500 m²/g, less than or equal to about 1200 m²/g, less than or equal to about 1000 m²/g, less than or equal to about 500 m²/g, less than or equal to about 400 m²/g, less than or equal to about 300 m²/g, less than or equal to about 200 m²/g, less than or equal to about 150 m²/g, less than or equal to about 100 m²/g, less than or equal to about 90 m²/g, less than or equal to about 80 m²/g, or less than or equal to about 75 m²/g.

The carbon nanoparticle may be electrically conductive. The carbon nanoparticle may have an intrinsic resistivity of less than or equal to about 200 ohm·cm, (ohm·centimeters) for example, less than or equal to about 100 ohm·cm, less than or equal to about 90 ohm·cm, less than or equal to about 80 ohm·cm, less than or equal to about 70 ohm·cm, less than or equal to about 60 ohm·cm, less than or equal to about 50 ohm·cm, less than or equal to about 40 ohm·cm, less than or equal to about 30 ohm·cm, less than or equal to about 20 ohm·cm, less than or equal to about 10 ohm·cm, less than or equal to about 9 ohm·cm, less than or equal to about 8 ohm·cm, less than or equal to about 7 ohm·cm, less than or equal to about 6 ohm·cm, less than or equal to about 5 ohm·cm, less than or equal to about 4 ohm·cm, less than or equal to about 3 ohm·cm, less than or equal to about 2 ohm·cm, or less than or equal to about 1 ohm·cm. The carbon nanoparticle may have an intrinsic resistivity that is greater than or equal to about 0.001 ohm·cm, greater than or equal to about 0.005 ohm·cm, greater than or equal to about 0.1 ohm·cm, greater than or equal to about 0.3 ohm·cm, greater than or equal to about 0.5 ohm·cm, greater than or equal to about 0.7 ohm·cm, greater than or equal to about 0.9 ohm·cm, or greater than or equal to about 1 ohm·cm.

The carbon nanoparticle may have a carbon content of greater than or equal to about 95 wt %, greater than or equal to about 96 wt %, greater than or equal to about 97 wt %, greater than or equal to about 98 wt %, or greater than or equal to about 99 wt %. In the carbon nanoparticle, the carbon content may be less than or equal to about 100 wt %, less than or equal to about 99.9 wt %, or less than or equal to about 99.7 wt %.

The carbon nanoparticle may further include a carboxylic acid group or a hydroxyl group on its surface. The carbon nanoparticle may be surface-treated. A reagent for the surface treatment may be an acid, a base, an oxidizing agent, a reducing agent, or a combination thereof. The acid may be a strong acid such as a sulfuric acid or a hydrochloric acid. The base may be a strong base.

An embodiment of the emission layer includes a semiconductor nanoparticle and a carbon nanoparticle, and accordingly, may exhibit a relatively high carbon content. In an embodiment, the amount of the carbon nanoparticle in the emission layer may be greater than or equal to about 0.001 weight percentages (wt %), greater than or equal to about 0.003 wt %, greater than or equal to about 0.005 wt %, greater than or equal to about 0.007 wt %, greater than or equal to about 0.009 wt %, greater than or equal to about 0.01 wt %, greater than or equal to about 0.02 wt %, greater than or equal to about 0.03 wt %, greater than or equal to about 0.04 wt %, greater than or equal to about 0.05 wt %, greater than or equal to about 0.06 wt %, greater than or equal to about 0.07 wt %, greater than or equal to about 0.08 wt %, greater than or equal to about 0.09 wt %, greater than or equal to about 0.1 wt %, greater than or equal to about 0.2 wt %, greater than or equal to about 0.3 wt %, greater than or equal to about 0.4 wt %, greater than or equal to about 0.5 wt %, greater than or equal to about 0.6 wt %, greater than or equal to about 0.7 wt %, greater than or equal to about 0.8 wt %, greater than or equal to about 0.9 wt %, greater than or equal to about 1 wt %, greater than or equal to about 1.2 wt %, greater than or equal to about 1.5 wt %, greater than or equal to about 1.7 wt %, greater than or equal to about 1.9 wt %, greater than or equal to about 2 wt %, greater than or equal to about 2.3 wt %, greater than or equal to about 2.5 wt %, greater than or equal to about 2.7 wt %, greater than or equal to about 3 wt %, greater than or equal to about 3.3 wt %, greater than or equal to about 3.5 wt %, greater than or equal to about 3.7 wt %, greater than or equal to about 4 wt %, greater than or equal to about 4.3 wt %, greater than or equal to about 4.5 wt %, greater than or equal to about 4.7 wt %, greater than or equal to about 5 wt %, greater than or equal to about 5.3 wt %, greater than or equal to about 5.5 wt %, greater than or equal to about 5.7 wt %, greater than or equal to about 6 wt %, greater than or equal to about 6.3 wt %, greater than or equal to about 6.5 wt %, greater than or equal to about 6.7 wt %, greater than or equal to about 7 wt %, greater than or equal to about 7.3 wt %, greater than or equal to about 7.5 wt %, greater than or equal to about 8 wt %, greater than or equal to about 8.3 wt %, greater than or equal to about 8.5 wt %, greater than or equal to about 8.7 wt %, greater than or equal to about 9 wt %, greater than or equal to about 9.3 wt %, greater than or equal to about 9.5 wt %, greater than or equal to about 9.7 wt %, or greater than or equal to about 10 wt %, based on the total weight of the semiconductor nanoparticle or the total weight of the emission layer.

In an embodiment, the amount of the carbon nanoparticle in the emission layer may be less than or equal to about 33 wt %, less than or equal to about 30 wt %, less than or equal to about 29 wt %, less than or equal to about 28 wt %, less than or equal to about 27 wt %, less than or equal to about 26 wt %, less than or equal to about 25 wt %, less than or equal to about 24 wt %, less than or equal to about 23 wt %, less than or equal to about 22 wt %, less than or equal to about 21 wt %, less than or equal to about 20 wt %, less than or equal to about 19 wt %, less than or equal to about 18 wt %, less than or equal to about 17 wt %, less than or equal to about 16 wt %, less than or equal to about 15 wt %, less than or equal to about 14 wt %, less than or equal to about 13 wt %, less than or equal to about 12 wt %, less than or equal to about 11 wt %, or less than or equal to about 10.5 wt %, based on the total weight of the semiconductor nanoparticle or the total weight of the emission layer.

In an embodiment, the semiconductor nanoparticle may include zinc and selenium, and in the emission layer, a mole ratio of carbon to zinc may be greater than or equal to about 0.25:1, greater than or equal to about 0.27:1, greater than or equal to about 0.29:1, greater than or equal to about 0.3:1, greater than or equal to about 0.31:1, greater than or equal to about 0.33:1, greater than or equal to about 0.35:1, greater than or equal to about 0.37:1, greater than or equal to about 0.39:1, greater than or equal to about 0.4:1, greater than or equal to about 0.41:1, greater than or equal to about 0.43:1, greater than or equal to about 0.45:1, greater than or equal to about 0.47:1, greater than or equal to about 0.49:1, greater than or equal to about 0.5:1, greater than or equal to about 0.53:1, greater than or equal to about 0.55:1, greater than or equal to about 0.57:1, greater than or equal to about 0.59:1, greater than or equal to about 0.6:1, greater than or equal to about 0.61:1, greater than or equal to about 0.63:1, greater than or equal to about 0.65:1, greater than or equal to about 0.67:1, greater than or equal to about 0.69:1, greater than or equal to about 0.7:1, greater than or equal to about 0.71:1, greater than or equal to about 0.73:1, greater than or equal to about 0.75:1, greater than or equal to about 0.77:1, greater than or equal to about 0.79:1, greater than or equal to about 0.8:1, greater than or equal to about 0.81:1, greater than or equal to about 0.83:1, greater than or equal to about 0.85:1, greater than or equal to about 0.87:1, greater than or equal to about 0.89:1, greater than or equal to about 0.9:1, greater than or equal to about 0.91:1, greater than or equal to about 0.93:1, greater than or equal to about 0.95:1, greater than or equal to about 0.97:1, greater than or equal to about 0.99:1, greater than or equal to about 1:1, greater than or equal to about 1.5:1, greater than or equal to about 2:1, greater than or equal to about 2.5:1, greater than or equal to about 3:1, greater than or equal to about 3.5:1, greater than or equal to about 4:1, or greater than or equal to about 4.5:1. In the emission layer, a mole ratio of carbon to zinc may be less than or equal to about 1000:1, less than or equal to about 500:1, less than or equal to about 400:1, less than or equal to about 300:1, less than or equal to about 200:1, less than or equal to about 100:1, less than or equal to about 90:1, less than or equal to about 80:1, less than or equal to about 70:1, less than or equal to about 60:1, less than or equal to about 50:1, less than or equal to about 40:1, less than or equal to about 30:1, less than or equal to about 20:1, less than or equal to about 10:1, less than or equal to about 9:1, less than or equal to about 8:1, less than or equal to about 7:1, less than or equal to about 6:1, less than or equal to about 5:1, less than or equal to about 4.4:1, less than or equal to about 3.2:1, less than or equal to about 2.7:1, less than or equal to about 2.1:1, or less than or equal to about 1.8:1.

In an embodiment, the semiconductor nanoparticle may include zinc and a chalcogen element (e.g., selenium, sulfur, or a combination thereof), and in the emission layer, a mole ratio of carbon to the chalcogen element (e.g., the mole ratio of carbon to selenium, the mole ratio of carbon to sulfur, or the mole ratio of carbon to the total of selenium and sulfur) may be greater than or equal to about 0.15:1, greater than or equal to about 0.17:1, greater than or equal to about 0.19:1, greater than or equal to about 0.2:1, greater than or equal to about 0.21:1, greater than or equal to about 0.25:1, greater than or equal to about 0.27:1, greater than or equal to about 0.29:1, greater than or equal to about 0.3:1, greater than or equal to about 0.31:1, greater than or equal to about 0.33:1, greater than or equal to about 0.35:1, greater than or equal to about 0.37:1, greater than or equal to about 0.39:1, greater than or equal to about 0.4:1, greater than or equal to about 0.41:1, greater than or equal to about 0.43:1, greater than or equal to about 0.45:1, greater than or equal to about 0.47:1, greater than or equal to about 0.49:1, greater than or equal to about 0.5:1, greater than or equal to about 0.53:1, greater than or equal to about 0.55:1, greater than or equal to about 0.57:1, greater than or equal to about 0.59:1, greater than or equal to about 0.6:1, greater than or equal to about 0.61:1, greater than or equal to about 0.63:1, greater than or equal to about 0.65:1, greater than or equal to about 0.67:1, greater than or equal to about 0.69:1, greater than or equal to about 0.7:1, greater than or equal to about 0.71:1, greater than or equal to about 0.73:1, greater than or equal to about 0.75:1, greater than or equal to about 0.77:1, greater than or equal to about 0.79:1, greater than or equal to about 0.8:1, greater than or equal to about 0.81:1, greater than or equal to about 0.83:1, greater than or equal to about 0.85:1, greater than or equal to about 0.87:1, greater than or equal to about 0.89:1, greater than or equal to about 0.9:1, greater than or equal to about 0.91:1, greater than or equal to about 0.93:1, greater than or equal to about 0.95:1, greater than or equal to about 0.97:1, greater than or equal to about 0.99:1, greater than or equal to about 1:1, greater than or equal to about 1.1:1, greater than or equal to about 1.2:1, greater than or equal to about 1.3:1, greater than or equal to about 1.4:1, greater than or equal to about 1.5:1, greater than or equal to about 1.6:1, greater than or equal to about 1.7:1, greater than or equal to about 1.8:1, greater than or equal to about 1.9:1, greater than or equal to about 2:1, greater than or equal to about 2.1:1, greater than or equal to about 2.2:1, greater than or equal to about 2.3:1, greater than or equal to about 2.4:1, greater than or equal to about 2.5:1, greater than or equal to about 2.6:1, greater than or equal to about 2.7:1, greater than or equal to about 2.8:1, greater than or equal to about 2.9:1, greater than or equal to about 3:1, greater than or equal to about 3.1:1, greater than or equal to about 3.2:1, greater than or equal to about 3.3:1, greater than or equal to about 3.4:1, greater than or equal to about 3.5:1, greater than or equal to about 3.6:1, greater than or equal to about 3.7:1, greater than or equal to about 3.8:1, greater than or equal to about 3.9:1, greater than or equal to about 4:1, greater than or equal to about 4.1:1, greater than or equal to about 4.2:1, greater than or equal to about 4.3:1, greater than or equal to about 4.4:1, greater than or equal to about 4.5:1, greater than or equal to about 4.6:1, greater than or equal to about 4.7:1, greater than or equal to about 4.8:1, greater than or equal to about 4.9:1, or greater than or equal to about 5:1.

In the emission layer, the mole ratio of carbon to the chalcogen element (e.g., the mole ratio of carbon to selenium, the mole ratio of carbon to sulfur, or the mole ratio of carbon to the total of selenium and sulfur) may be less than or equal to about 5000:1, less than or equal to about 4000:1, less than or equal to about 3000:1, less than or equal to about 2000:1, less than or equal to about 1000:1, less than or equal to about 900:1, less than or equal to about 800:1, less than or equal to about 700:1, less than or equal to about 600:1, less than or equal to about 500:1, less than or equal to about 400:1, less than or equal to about 300:1, less than or equal to about 200:1, less than or equal to about 100:1, less than or equal to about 90:1, less than or equal to about 80:1, less than or equal to about 70:1, less than or equal to about 60:1, less than or equal to about 50:1, less than or equal to about 40:1, less than or equal to about 30:1, less than or equal to about 20:1, less than or equal to about 10:1, less than or equal to about 9:1, less than or equal to about 8:1, less than or equal to about 7:1, less than or equal to about 6:1, less than or equal to about 5:1, less than or equal to about 4.4:1, less than or equal to about 3.2:1, less than or equal to about 2.7:1, less than or equal to about 2.1:1, or less than or equal to about 1.8:1.

In an embodiment of the electroluminescent device, the thickness of the emission layer may be appropriately selected. In an embodiment, the emission layer may include a monolayer or monolayers of the semiconductor nanoparticles. In another embodiment, the emission layer may include one or more monolayers of the semiconductor nanoparticles, for example, greater than or equal to about one layer, greater than or equal to about two layers, greater than or equal to about three layers, or greater than or equal to about four layers and less than or equal to about twenty layers, less than or equal to about ten layers, less than or equal to about nine layers, less than or equal to about eight layers, less than or equal to about seven layers, or less than or equal to about six layers. The emission layer may have a thickness of greater than or equal to about 5 nm, for example, greater than or equal to about 10 nm, greater than or equal to about 20 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The emission layer may have a thickness of about 10 nm to about 150 nm, for example, about 20 nm to about 100 nm, or for example, about 30 nm to about 50 nm.

The emission layer may have a single-layer structure or a multilayer structure in which two or more layers are stacked. In the multilayer structure, adjacent layers (e.g., a first emission layer and a second emission layer) may be configured to emit the same color (green light, blue light, or red light). In the multilayer structure, the adjacent layers (e.g., the first emission layer and the second emission layer) may have the same or different compositions and/or ligands.

The emission layer may not (substantially) include (or may be substantially free of) electrically insulating polymer. For example, a composition for forming the emission layer may not include or substantially not include an insulating polymer or a monomer thereof. In the emission layer, the content of the electrically insulating polymer, based on the total weight of the emission layer, may be less than or equal to about 1 wt %, less than or equal to about 0.5 wt %, or less than or equal to about 0.1 wt %. The emission layer may exhibit increased electrical conductivity without an increase in leakage current. An embodiment of the electroluminescent device may exhibit increased current density at a predetermined voltage.

In an embodiment, the electroluminescent device may include a charge (hole or electron) auxiliary layer between a first electrode and a second electrode (e.g., between the first electrode 10 and the second electrode 50). In an embodiment, the electroluminescent display device may include a hole auxiliary layer 20 or an electron auxiliary layer 40 between the first electrode 10 and the emission layer 30 and/or between the second electrode 50 and the emission layer 30 (see FIG. 2 and FIG. 3).

An embodiment of the light emitting device may further include a hole auxiliary layer. The hole auxiliary layer 20 is positioned between the first electrode 10 and the emission layer 30. The hole auxiliary layer 20 may include a hole injection layer, a hole transport layer, and/or an electron (or hole) blocking layer. The hole auxiliary layer 20 may be a single-component layer or a multilayer structure in which adjacent layers include different components.

The HOMO energy level of the hole auxiliary layer 20 may be matched with the HOMO energy level of the emission layer 30 to enhance the mobility of holes transferred from the hole auxiliary layer 20 to the emission layer 30. In an embodiment, the hole auxiliary layer 20 may include a hole injection layer positioned closer to the first electrode 10 and a hole transport layer positioned closer to the emission layer 30.

In an embodiment, the material included in the hole auxiliary layer 2, or 20 (e.g., a hole transport layer, a hole injection layer, or an electron blocking layer), is not particularly limited, and may include, for example, poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene): polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenyl]cyclohexane (TAPC), a p-type metal oxide (e.g., NiO, WO₃, MoO₃, etc.), a carbon-based material such as graphene oxide, or a combination thereof, but is not limited thereto.

In the hole auxiliary layer, a thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

The electron auxiliary layer 40 is positioned between the emission layer 30 and the second electrode 50. The electron auxiliary layer 40 may include, for example, an electron injection layer, an electron transport layer, and/or a hole (or electron) blocking layer. The electron auxiliary layer may include, for example, an electron injection layer (EIL) that facilitates the injection of electrons, an electron transport layer (ETL) that facilitates the transport of electrons, a hole blocking layer (HBL) that blocks the movement of holes, or a combination thereof. In an embodiment, the electron injection layer may be disposed between the electron transport layer and the second electrode. For example, the hole blocking layer may be disposed between the emission layer and the electron transport (injection) layer, but is not limited thereto. The thickness of each layer may be appropriately selected. For example, the thickness of each layer may be greater than or equal to about 1 nm and less than or equal to about 500 nm, but is not limited thereto. The electron injection layer may be an organic layer formed by deposition. The electron transport layer may include inorganic oxide nanoparticles or may be an organic layer formed by deposition.

The electron transport layer (ETL) and/or the electron injection layer, and/or the hole blocking layer may include 1,4,5,8-naphthalene-tetracarboxylic dianhydride (NTCDA), bathocuproine (BCP), tris[3-(3-pyridyl)-mesityl]borane (3TPYMB), LiF, tris(8-hydroxyquinoline)aluminum (Alq₃), tris(8-hydroxyquinoline)gallium (Gaq₃), tris-(8-hydroxyquinoline)indium (Inq₃), bis(8-hydroxyquinoline)zinc (Znq₂), bis(2-(2-hydroxyphenyl)benzothiazolate)zinc (Zn(BTZ)₂), bis(10-hydroxybenzo[h]quinolinato)beryllium (BeBq₂), 8-(4-(4,6-di(naphthalen-2-yl)-1,3,5-triazin-2-yl)phenyl) quinolone (ET204), 8-hydroxyquinolinato lithium (Liq), a zinc oxide nanoparticle, a n-type doped zinc metal oxide nanoparticle or zinc oxide nanoparticle, a hafnium oxide nanoparticle, or a combination thereof.

The electron auxiliary layer 40 may include an electron transport layer. The electron transport layer may include a plurality of nanoparticles. The plurality of nanoparticles may include a metal oxide containing zinc.

The metal oxide may include zinc oxide, zinc magnesium oxide, or a combination thereof. The metal oxide may include Zn₁₋ₓMₓO, where M is Mg, Ca, Zr, W, Li, Ti, Y, Al, or a combination thereof, and 0≤x≤0.5. In an embodiment, in Zn₁₋ₓMₓO, M may be magnesium (Mg). In an embodiment, in Zn₁₋ₓMₓO, x may be greater than or equal to about 0.01 and less than or equal to about 0.3, for example, less than or equal to about 0.25, less than or equal to about 0.2, or less than or equal to about 0.15.

The absolute value of the LUMO of the nanoparticles included in the emission layer may be greater than or less than the absolute value of the LUMO of the metal oxide.

An average size of the nanoparticles may be greater than or equal to about 1 nm, for example, greater than or equal to about 1.5 nm, greater than or equal to about 2 nm, greater than or equal to about 2.5 nm, or greater than or equal to about 3 nm, and less than or equal to about 10 nm, less than or equal to about 9 nm, less than or equal to about 8 nm, less than or equal to about 7 nm, less than or equal to about 6 nm, or less than or equal to about 5 nm.

In an embodiment, each of the electron auxiliary layers 40 (e.g., the electron injection layer, electron transport layer, or hole blocking layer) may have a thickness of greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the first electrode 10 disposed on the transparent substrate 100 may include a metal oxide-containing transparent electrode (e.g., an indium tin oxide (ITO) electrode), and the second electrode (cathode) 50 facing the first electrode 10 may include a conductive metal (e.g., having a relatively low work function, Mg, Al, or the like). The hole auxiliary layer 20 (e.g., a hole injection layer such as poly(3,4-ethylenedioxythiophene): polystyrene sulfonate (PEDOT:PSS) and/or p-type metal oxide and/or a hole transport layer such as 2-(trifluoromethyl)benzimidazole (TFB) and/or polyvinylcarbazole (PVK) may be provided between the first electrode 10 and the emission layer 30. The hole injection layer may be disposed close to the transparent electrode and the hole transport layer may be disposed close to the emission layer 30. The electron auxiliary layer 40 such as an electron injection/transport layer may be disposed between the emission layer 30 and the second electrode 50. (See FIG. 2)

A device according to another embodiment may have an inverted structure. As used herein, the second electrode 50 disposed on the transparent substrate 100 may include a metal oxide-containing transparent electrode (e.g., ITO), and the first electrode 10 facing the second electrode 50 may include a metal (e.g., having a relatively high work function, Au, Ag, or the like). For example, an (optionally doped) n-type metal oxide (crystalline Zn metal oxide) or the like may be disposed as an electron auxiliary layer 40 (e.g., an electron transport layer) between the second electrode 50 and the emission layer 30. MoO₃ or other p-type metal oxide may be disposed as a hole auxiliary layer 20 (e.g., a hole transport layer including TFB and/or PVK and/or a hole injection layer including MoO₃ or other p-type metal oxide) between the first electrode 10 and the emission layer 30. (Refer to FIG. 3)

Referring to FIG. 4A, an embodiment of the electroluminescent device includes an emission layer between a first electrode (anode) and a second electrode (cathode), or between an electron auxiliary layer (e.g., an electron transport layer) and a hole auxiliary layer (e.g., a hole transport layer). The emission layer includes semiconductor nanoparticles and carbon nanoparticles (e.g., carbon black). Upon application of a voltage, electrons are injected into the emission layer from the second electrode or the electron transport layer, and holes are injected into the emission layer through the first electrode or the hole transport layer. The injected electrons and holes may recombine within the emission layer to form excitons and emit light.

A method of manufacturing an embodiment of the electroluminescent device includes providing one of a first electrode and a second electrode; forming an emission layer on the provided electrode; and providing the remaining one of the first electrode and the second electrode on the emission layer. The forming of the emission layer may include obtaining an emission layer-forming composition including carbon nanoparticles and semiconductor nanoparticles in an organic solvent; and forming the emission layer by applying the emission layer-forming composition.

In an embodiment, the electroluminescent device may be fabricated by optionally forming a hole auxiliary layer (e.g., by deposition or coating) on a substrate on which an electrode is formed, forming an emission layer including a semiconductor nanoparticle (e.g., a pattern of the semiconductor nanoparticle), and forming (optionally, an electron auxiliary layer and) an electrode on the emission layer (e.g., by deposition or coating). Detailed descriptions of the first electrode, second electrode, hole auxiliary layer, electron auxiliary layer, emission layer, carbon nanoparticles, and semiconductor nanoparticles are as described above.

The method for forming the electrodes, the hole auxiliary layer, and the electron auxiliary layer may be appropriately selected and is not particularly limited. In an embodiment, the electrodes, the hole auxiliary layer, and the electron auxiliary layer may each be formed using various techniques such as vacuum deposition, spin coating, casting, the Langmuir-Blodgett (LB) method, inkjet printing, laser printing, or laser induced thermal imaging (LITI). When the electrode, the hole auxiliary layer, or the electron auxiliary layer is formed by vacuum deposition, the deposition conditions may be appropriately selected. In an embodiment, the deposition temperature may be from about 100° C. to about 500° C., the vacuum level may be from about 10-8 to about 10-3 torr, and the deposition rate may be in a range from about 0.01 Å/sec to about 100 Å/sec. The deposition conditions may be selected in consideration of the material to be included in the layer to be formed and the structure of the layer to be formed.

In an embodiment, the emission layer may be formed by applying an emission layer-forming composition onto the electrode and/or the charge auxiliary layer. The emission layer-forming composition includes a semiconductor nanoparticle, a carbon nanoparticle, and an organic solvent. The method of application is not particularly limited and may include, for example, a spin coating, an inkjet printing, or the like. In an embodiment, the emission layer-forming composition may form a composition (ink) suitable for an inkjet printing process, and an emission layer pattern may be provided through the inkjet printing process.

The emission layer-forming composition may be prepared by dispersing the semiconductor nanoparticle and the carbon nanoparticle in the organic solvent. The carbon nanoparticle may be subjected to heat treatment before being dispersed in the organic solvent. The heat treatment temperature may be greater than or equal to about 80° C., greater than or equal to about 100° C., greater than or equal to about 150° C., greater than or equal to about 200° C., greater than or equal to about 250° C., or greater than or equal to about 300° C. The heat treatment temperature may be less than or equal to about 500° C., less than or equal to about 450° C., less than or equal to about 400° C., less than or equal to about 350° C., less than or equal to about 300° C., less than or equal to about 280° C., less than or equal to about 240° C., or less than or equal to about 190° C. The heat-treated carbon nanoparticle may be well dispersed in the organic solvent described below.

In an embodiment, the preparation of the emission layer-forming composition may include simultaneously or sequentially adding the semiconductor nanoparticle and the carbon nanoparticle into an organic solvent. In an embodiment, the preparation of the emission layer-forming composition may include preparing a semiconductor nanoparticle dispersion by dispersing a semiconductor nanoparticle in an organic solvent, and preparing a carbon nanoparticle dispersion by dispersing a carbon nanoparticle in an organic solvent; and mixing the prepared dispersion at a predetermined ratio.

In an embodiment, the preparation of the emission layer-forming composition may further include agitating, for example, to achieve uniform dispersion of the particle such as the semiconductor nanoparticle, the carbon nanoparticle, or a combination thereof. The agitation may include sonication of the dispersion. The semiconductor nanoparticle, the carbon nanoparticle, or both may form a colloidal dispersion in the organic solvent.

In the emission layer-forming composition, the content ratio between the carbon nanoparticle and the semiconductor nanoparticle may be appropriately selected in consideration of the desired ratio between them in the final emission layer.

In an embodiment of the emission layer-forming composition, the content of the carbon nanoparticle, based on the total weight of the semiconductor nanoparticle, may be greater than or equal to about 0.001 wt %, greater than or equal to about 0.003 wt %, greater than or equal to about 0.005 wt %, greater than or equal to about 0.007 wt %, greater than or equal to about 0.009 wt %, greater than or equal to about 0.01 wt %, greater than or equal to about 0.02 wt %, greater than or equal to about 0.03 wt %, greater than or equal to about 0.04 wt %, greater than or equal to about 0.05 wt %, greater than or equal to about 0.06 wt %, greater than or equal to about 0.065 wt %, greater than or equal to about 0.07 wt %, greater than or equal to about 0.08 wt %, greater than or equal to about 0.09 wt %, greater than or equal to about 0.1 wt %, greater than or equal to about 0.2 wt %, greater than or equal to about 0.3 wt %, greater than or equal to about 0.4 wt %, greater than or equal to about 0.5 wt %, greater than or equal to about 0.6 wt %, greater than or equal to about 0.65 wt %, greater than or equal to about 0.7 wt %, greater than or equal to about 0.8 wt %, greater than or equal to about 0.9 wt %, greater than or equal to about 1 wt %, greater than or equal to about 1.2 wt %, greater than or equal to about 1.5 wt %, greater than or equal to about 1.7 wt %, greater than or equal to about 1.9 wt %, greater than or equal to about 2 wt %, greater than or equal to about 2.3 wt %, greater than or equal to about 2.5 wt %, greater than or equal to about 2.7 wt %, greater than or equal to about 3 wt %, greater than or equal to about 3.3 wt %, greater than or equal to about 3.5 wt %, greater than or equal to about 3.7 wt %, greater than or equal to about 4 wt %, greater than or equal to about 4.3 wt %, greater than or equal to about 4.5 wt %, greater than or equal to about 4.7 wt %, greater than or equal to about 5 wt %, greater than or equal to about 5.3 wt %, greater than or equal to about 5.5 wt %, greater than or equal to about 5.7 wt %, greater than or equal to about 6 wt %, greater than or equal to about 6.3 wt %, greater than or equal to about 6.5 wt %, greater than or equal to about 6.7 wt %, greater than or equal to about 7 wt %, greater than or equal to about 7.3 wt %, greater than or equal to about 7.5 wt %, greater than or equal to about 8 wt %, greater than or equal to about 8.3 wt %, greater than or equal to about 8.5 wt %, greater than or equal to about 8.7 wt %, greater than or equal to about 9 wt %, greater than or equal to about 9.3 wt %, greater than or equal to about 9.5 wt %, greater than or equal to about 9.7 wt %, or greater than or equal to about 10 wt %.

In an embodiment of the emission layer-forming composition, the content of the carbon nanoparticle, based on the total weight of the semiconductor nanoparticle, may be less than or equal to about 20 wt %, less than or equal to about 19 wt %, less than or equal to about 18 wt %, less than or equal to about 17 wt %, less than or equal to about 16 wt %, less than or equal to about 15 wt %, less than or equal to about 14 wt %, less than or equal to about 13 wt %, less than or equal to about 12 wt %, less than or equal to about 11 wt %, less than or equal to about 10.5 wt %, less than or equal to about 10 wt %, less than or equal to about 9.2 wt %, less than or equal to about 8.8 wt %, less than or equal to about 7.2 wt %, less than or equal to about 6.8 wt %, less than or equal to about 5.6 wt %, less than or equal to about 4.2 wt %, less than or equal to about 3.8 wt %, less than or equal to about 2.4 wt %, less than or equal to about 1.2 wt %, less than or equal to about 0.85 wt %, less than or equal to about 0.72 wt %, or less than or equal to about 0.68 wt %.

A concentration of the semiconductor nanoparticle and the carbon nanoparticle in the emission layer-forming composition may also be appropriately selected and are not particularly limited. In an embodiment, the concentration of the semiconductor nanoparticle may be from about 0.1 mg/mL to less than or equal to about 50 mg/mL, from about 1 mg/mL to less than or equal to about 40 mg/mL, from about 3 mg/mL to less than or equal to about 25 mg/mL, from about 5 mg/ml to less than or equal to about 20 mg/mL, from about 12 mg/mL to about 18 mg/mL, from about 15 mg/mL to about 16 mg/mL, or within a combination of these ranges. In an embodiment, the concentration of the carbon nanoparticle may be from about 0.0001 mg/mL to less than or equal to about 10 mg/mL, from about 0.001 mg/mL to less than or equal to about 9 mg/mL, from about 0.005 mg/mL to less than or equal to about 8 mg/mL, from about 0.01 mg/mL to less than or equal to about 7 mg/mL, from about 0.1 mg/mL to less than or equal to about 6 mg/mL, from about 0.5 mg/mL to less than or equal to about 5 mg/mL, or within a combination of these ranges.

The organic solvent may be an organic solvent capable of dispersing the semiconductor nanoparticle and the carbon nanoparticle. In an embodiment, the organic solvent may be an organic solvent having a relatively high boiling point at atmospheric pressure. The boiling point of the organic solvent may be greater than or equal to about 120° C., greater than or equal to about 130° C., greater than or equal to about 140° C., greater than or equal to about 150° C., greater than or equal to about 160° C., greater than or equal to about 170° C., greater than or equal to about 180° C., greater than or equal to about 200° C., greater than or equal to about 230° C., greater than or equal to about 250° C., greater than or equal to about 300° C., greater than or equal to about 350° C., or greater than or equal to about 360° C. The boiling point of the organic solvent may be less than or equal to about 380° C., less than or equal to about 300° C., less than or equal to about 280° C., less than or equal to about 270° C., less than or equal to about 250° C., or less than or equal to about 200° C. The organic solvent may be a predetermined solvent described herein. The organic solvent may include a substituted or unsubstituted aromatic solvent such as cyclohexylbenzene, toluene, or xylene; a substituted or unsubstituted C6 to C20 aliphatic hydrocarbon solvent such as hexane, octane, or decane; or a combination thereof.

The emission layer-forming composition may exhibit a viscosity suitable for a predetermined process (e.g., an inkjet printing process). The viscosity may be in a range of about 0.5 centipoise (cPs) to about 30 cPs, about 1 cPs to about 15 cPs, about 1.5 cPs to about 10 cPs, about 2 cPs to about 8 cPs, about 2.5 cPs to about 5 cPs, about 2.8 cPs to about 3.5 cPs, or within a combination of these ranges.

The emission layer-forming composition may exhibit a surface tension or a wettability with respect to the electrode or the charge auxiliary layer (e.g., the hole auxiliary layer). The surface tension may be in a range of about 10 millinewtons per meter (mN/m) to about 100 mN/m, about 15 mN/m to about 80 mN/m, about 20 mN/m to about 50 mN/m, about 25 mN/m to about 45 mN/m, about 30 mN/m to about 40 mN/m, about 33 mN/m to about 38 mN/m, or within a combination of these ranges.

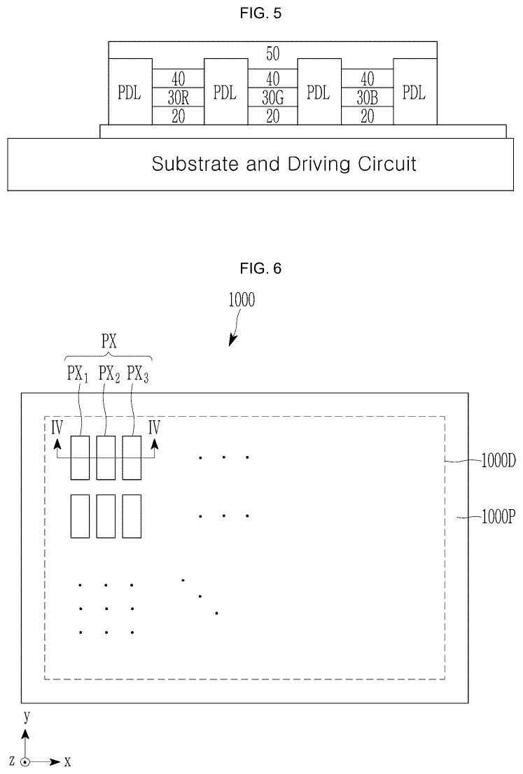

In an embodiment, the method of applying or depositing the emission layer-forming composition is not particularly limited. The method may include, but is not limited to, a spin coating, a blade coating, an inkjet printing, or the like. In an embodiment, forming the emission layer by inkjet printing may include loading an ink composition containing semiconductor nanoparticles into a device equipped with an inkjet printing nozzle, and discharging or depositing droplets of the composition from the nozzle toward a desired location (e.g., a surface of a hole transport layer or an electron transport layer defined by a pixel defining layer (PDL) or a partition or bank) (see FIG. 4A and FIG. 5).

The method may include forming the emission layer by removing the organic solvent from the film obtained by applying or depositing the emission layer-forming composition. The removal of the organic solvent may include heat-treating (e.g., heating) the film. The heating temperature may be greater than or equal to about 115° C., greater than or equal to about 120° C., greater than or equal to about 125° C., greater than or equal to about 130° C., greater than or equal to about 135° C., greater than or equal to about 140° C., greater than or equal to about 145° C., greater than or equal to about 150° C., or greater than or equal to about 155° C. The heating temperature may be less than about 180° C., less than or equal to about 175° C., less than or equal to about 170° C., less than or equal to about 165° C., less than or equal to about 160° C., or less than or equal to about 155° C. The heat treatment may be performed under an inert gas atmosphere.

The method of an embodiment may further include forming an electron auxiliary layer on the formed emission layer. The step of forming the electron auxiliary layer (e.g., an electron transport layer) may include forming a film including the zinc oxide nanoparticles on the multilayer emission layer. The step of forming the film may include preparing a composition (e.g., a dispersion) containing the zinc oxide nanoparticles and applying it onto the multilayer emission layer. The composition or the dispersion may further include an organic solvent. The method may include heat-treating the formed film.

The details regarding the zinc oxide nanoparticles are as described above. The preparation of the composition may include adding the zinc metal oxide nanoparticles to an organic solvent. The organic solvent may include a C1 to C10 alcohol solvent (e.g., ethanol, methanol, propanol, butanol, pentanol, etc.), or a combination thereof.

The coated film may be heat-treated at a predetermined temperature, for example, at a temperature of greater than or equal to about 50° C. or less than or equal to about 250° C., or at a temperature of greater than or equal to about 80° C. and less than or equal to about 120° C., to remove the organic solvent or the like. The heat treatment may be performed, for example, under an inert gas atmosphere such as nitrogen or argon, or under ambient conditions. The heat treatment temperature may be less than about 120° C., less than or equal to about 115° C., less than or equal to about 110° C., less than or equal to about 105° C., less than or equal to about 100° C., less than or equal to about 95° C., less than or equal to about 90° C., or less than or equal to about 85° C. The heat treatment temperature may be greater than or equal to about 40° C., greater than or equal to about 50° C., greater than or equal to about 60° C., greater than or equal to about 65° C., greater than or equal to about 70° C., or greater than or equal to about 75° C.

The electroluminescent device may be configured to emit blue light. The wavelength range of blue light is as described above. The electroluminescent device may be configured to emit green light. The wavelength range of green light is as described above. The electroluminescent device may be configured to emit red light. The wavelength range of red light is as described above.

The electroluminescent device may have a maximum external quantum efficiency of greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The electroluminescent device may have a maximum external quantum efficiency of less than or equal to about 50%, less than or equal to about 40%, less than or equal to about 30%, or less than or equal to about 20%.

The electroluminescent device may have a maximum luminance of greater than or equal to about 1000 nit (cd/m²), greater than or equal to about 3000 nit, greater than or equal to about 4000 nit, greater than or equal to about 5000 nit, greater than or equal to about 6000 nit, or greater than or equal to about 7000 nit. The maximum luminance may be in a range of about 3000 nit to about 100,000 nit, about 4000 nit to about 80,000 nit, or about 5000 nit to about 50,000 nit.

The electroluminescent device may exhibit improved lifetime. In an embodiment, the lifetime of the electroluminescent device may be measured by driving the device at a predetermined initial luminance (e.g., 146 nit or 650 nit). The lifetime T50 of the electroluminescent device may be greater than or equal to about 10 hours, greater than or equal to about 50 hours, greater than or equal to about 80 hours, greater than or equal to about 100 hours, greater than or equal to about 120 hours, greater than or equal to about 130 hours, greater than or equal to about 150 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1000 hours, or greater than or equal to about 1500 hours.

The lifetime T90 of the electroluminescent device may be greater than or equal to about 10 hours, greater than or equal to about 15 hours, greater than or equal to about 20 hours, greater than or equal to about 25 hours, greater than or equal to about 30 hours, greater than or equal to about 35 hours, greater than or equal to about 40 hours, greater than or equal to about 50 hours, greater than or equal to about 75 hours, greater than or equal to about 100 hours, greater than or equal to about 125 hours, greater than or equal to about 150 hours, greater than or equal to about 175 hours, greater than or equal to about 200 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1000 hours, or greater than or equal to about 1500 hours.

In an embodiment, T50 may be about 150 hours to about 5000 hours, about 400 hours to about 4000 hours, about 500 hours to about 3500 hours, about 750 hours to about 2000 hours, about 1000 hours to about 1500 hours, or a combination thereof.

In an embodiment, T90 may be in a range of about 13 hours to about 5000 hours, about 15 hours to about 2800 hours, about 18 hours to about 1200 hours, about 22 hours to about 1000 hours, about 31 hours to about 800 hours, about 50 hours to about 700 hours, about 60 hours to about 500 hours, about 80 hours to about 400 hours, or a combination thereof.

In an embodiment, a display device (e.g., a display panel) includes the electroluminescent device described herein.

The display device (e.g., a display panel) may include a first pixel and a second pixel configured to emit light of a different color from the first pixel. In an embodiment, the first light from the emission layer may be extracted (e.g., in the z direction) through the second electrode (Refer to FIG. 4 or FIG. 5). In an embodiment, the first light may be extracted through the (transparent) first electrode and optionally the substrate 100 (Refer to FIG. 3). The emission layer may be arranged within a pixel (or subpixel) in a display device (display panel) described later. (Refer to FIG. 4 A or FIG. 5)

Referring to FIG. 6, a display panel 1000 according to an embodiment may include a display area 1000D for displaying an image and, optionally, a non-display area 1000P located around the display area 1000D and having a bonding material disposed thereon.

The display area 1000D may include a plurality of pixels PX arranged along rows (e.g., in the x direction) and/or columns (e.g., in the y direction), and each pixel PX may include a plurality of subpixels PX₁, PX₂, and PX₃ that display different colors. Here, as an example, a configuration in which three subpixels PX₁, PX₂, and PX₃ form one pixel is illustrated, but the present disclosure is not limited thereto and may further include additional subpixels such as a white subpixel, or may further include one or more subpixels displaying the same color. The plurality of subpixels PX₁, PX₂, and PX₃ may be arranged in, for example, a Bayer matrix, a PenTile matrix, and/or a diamond matrix, but is not limited thereto.

Each subpixel PX₁, PX₂, and PX₃ may display a color of three primary colors or a combination of three primary colors, for example, red, green, blue, or a combination thereof. For example, a first subpixel PX₁ may display red, a second subpixel PX₂ may display green, and a third subpixel PX₃ may display blue.

Although the drawing illustrates an example in which all subpixels have the same size, the present disclosure is not limited thereto, and at least one of the subpixels may be larger or smaller than the other subpixels. Although the drawing illustrates an example in which all subpixels have the same shape, the present disclosure is not limited thereto, and at least one of the subpixels may have a different shape from the other subpixels.

In an embodiment, the display panel may include a light emitting panel (refer to FIG. 7) including a substrate 110, a buffer layer 111, a thin film transistor TFT, and a light emitting device 180. The display panel may include circuit elements for switching and/or driving each light emitting device.

Referring to FIG. 7, in the light emitting panel, light emitting devices 180 may be arranged in each subpixel PX₁, PX₂, and PX₃, and the light emitting devices 180 arranged in the subpixels PX₁, PX₂, and PX₃ may be driven independently. The subpixel may include a blue pixel, a red pixel, or a green pixel. At least one of the light emitting devices 180 may be an electroluminescent device according to an embodiment.

The substrate 110 is as described above. The buffer layer 111 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The buffer layer 111 may have one layer or two or more layers and may cover the entire surface of the substrate 110. The buffer layer 111 may be omitted.

The thin film transistor TFT may be a three-terminal device for switching and/or driving a light emitting device 180, and one or more thin film transistors TFT may be included for each subpixel. The thin film transistor TFT includes a gate electrode 124, a semiconductor layer 154 overlapped with the gate electrode 124, a gate insulating film 140 between the gate electrode 124 and the semiconductor layer 154, and a source electrode 173 and a drain electrode 175 electrically connected to the semiconductor layer 154. A coplanar top gate structure is shown as an example, but is not limited thereto and the thin film transistor TFT may have various structures.

The gate electrode 124 is electrically connected to a gate line (not shown) and may include a low-resistance metal such as aluminum (Al), molybdenum (Mo), copper (Cu), titanium (Ti), silver (Ag), gold (Au), alloys thereof, or a combination thereof, but is not limited thereto.

The semiconductor layer 154 may be an inorganic semiconductor such as amorphous silicon, polycrystalline silicon, an oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but is not limited thereto. The semiconductor layer 154 may include a channel region and a doped region disposed on both sides of the channel region and electrically connected to the source electrode 173 and the drain electrode 175, respectively.

The gate insulating film 140 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The drawing shows an example in which the gate insulating film 140 is formed on the entire surface of the substrate 110, but is not limited thereto and the gate insulating film 140 may be selectively formed between the gate electrode 124 and the semiconductor layer 154. The gate insulating film 140 may have one layer or two or more layers.

The source electrode 173 and the drain electrode 175 may include a low-resistance metal such as aluminum (Al), molybdenum (Mo), copper (Cu), titanium (Ti), silver (Ag), gold (Au), alloys thereof, or a combination thereof, but is not limited thereto. The source electrode 173 and the drain electrode 175 may each be electrically connected to the doping region of the semiconductor layer 154. The source electrode 173 may be electrically connected to a data line (not shown), and the drain electrode 175 is electrically connected to a light emitting device 180 described later.

An interlayer insulating film 145 may be additionally formed between the gate electrode 124 and the source/drain electrodes 173 and 175. The interlayer insulating film 145 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The interlayer insulating film 145 may have one layer or two or more layers.

In an embodiment, a protective film 160 may be formed on a thin film transistor TFT. The protective film 160 may be, for example, a passivation film, but is not limited thereto. The protective film 160 may include an organic, inorganic, or organic-inorganic material, and may include polyacrylic acid, polyimide, polyamide, polyamideimide, or a combination thereof, but is not limited thereto. The protective film 160 may have one or more layers.

In an embodiment, one of the first electrodes 1 and 10 and the second electrodes 5 and 50 may be a pixel electrode connected to the thin film transistor TFT and the other may be a common electrode.

The electroluminescent device of an embodiment or the display device including the same may be used in a top emission manner, a bottom emission manner, a double-sided emission manner, or a combination thereof.

In an embodiment, the first electrode 1, 10 may be a light transmitting electrode and the second electrode 5, 50 may be a reflective electrode, and the display panel may be a bottom emission type display panel that emits light toward the first electrode 10 and, if present, the substrate 110. In an embodiment, the first electrode 1, 10 may be a reflective electrode and the second electrode 5, 50 may be a light transmitting electrode, and the display panel may be a top emission type display panel that emits light opposite the first electrode 10 and, if present, the substrate 100. In an embodiment, both the first electrode and the second electrode may be light transmitting electrodes, and the display panel 1000 may be a both side emission type display panel that emits light to the substrate 110 side and the opposite side of the substrate 110.

The display device may include or may be a device or apparatus such as a virtual reality/augmented reality (VR/AR) device, a wearable device, a portable terminal device, a monitor, a computer, a laptop, a sensor, a television, an electronic display board, a camera, or an electrical/electronic component (for example, for an automobile).

Specific examples are described below. However, the examples described below are only for specifically illustrating or explaining the disclosure, and the scope of the disclosure is not limited thereto.

### EXAMPLES

### 1. Photoluminescence (PL) Analysis

A photoluminescence spectrum of a nanoparticle was obtained at room temperature using a Hitachi F-7000 spectrofluorometer or a Hamamatsu QY instrument (Quantaurus-QY Absolute PL quantum yield spectrophotometer C11347-11) with an excitation wavelength of 372 nm, and the absolute quantum yield (QY) was measured with an excitation wavelength of 400 nm.

### 2. Scanning Electron Microscopy (SEM) Analysis

Scanning electron microscopy analysis was performed using a FE-SEM (Nova 450_K, NovaNano SEM 450).

### 3. Electroluminescence Measurement

A current according to an applied voltage is measured with a Keithley 2635B source meter, and a CS2000 spectrometer is used to measure electroluminescent properties (e.g., luminance and EQE) of a light-emitting device.

### 4. Life-Span Characteristics

T50: As the device is started to be driven at a predetermined luminance (e.g., 146 nit), a time taken for a luminance of a given device to decrease to 50% of its initial luminance is measured.

T90: As the device is started to be driven at a predetermined luminance (e.g., 146 nit), a time taken for a luminance of a given device to decrease to 90% of its initial luminance is measured.

The following synthesis is performed under an inert gas atmosphere (e.g., under nitrogen) unless otherwise specified. A precursor content is provided as a molar content, unless otherwise specified.

### Reference Example 1

2 moles per liter (M) of a Se/trioctylphosphine (TOP) stock solution, 1M of a S/TOP stock solution, and 0.1M of a Te/TOP stock solution were prepared by dispersing selenium (Se), sulfur(S), and tellurium (Te) in trioctylphosphine (TOP), respectively. In a reactor containing trioctylamine, 0.125 millimoles (mmol) of zinc acetate was added to the reactor with oleic acid and heated at 120° C. under vacuum. After 1 hour, nitrogen was introduced into the reactor.

The reactor was heated to 300° C., and the Se/TOP stock solution and the Te/TOP stock solution in a Te:Se mole ratio of 1:20 were rapidly added to, e.g., injected into, the reactor. When the reaction was completed, the reaction mixture rapidly cooled to room temperature, and acetone was added to facilitate formation of a precipitate. The mixture (suspension) was centrifuged to separate the solids, and then the solids were dispersed in toluene, obtaining a ZnSeTe core (dispersion in toluene).

1.8 mmol of zinc acetate were added together with oleic acid to a flask containing trioctylamine and the prepared mixture was heated at 120° C. under vacuum for 10 minutes. Nitrogen (N₂) was then introduced into the reactor, and the reactor was heated to 180° C. The prepared ZnTeSe core particle dispersion was added quickly to the reactor, and the Se/TOP stock solution and the S/TOP stock solution were also added to the reactor at a mole ratio between Se and S of about 1:2, and the reactor temperature was raised to about 280° C. After the reaction was complete, and the reactor was cooled to room temperature and ethanol was added to facilitate precipitation of the semiconductor nanoparticles, which were separated by centrifuge. The separated nanoparticle emitting blue light was dispersed in toluene.

The prepared semiconductor nanoparticles emitted blue light of about 455 nanometers (nm).

### Reference Example 2: Preparation of Carbon Nanoparticles

For being used as carbon nanoparticles, a carbon black nanopowder (supplier: Alfa Aesar, product code: 045527, CAS No.: 1333-86-4) was heat-treated in air on a hot plate heated to 180° C. for 72 hours. The average particle size of the carbon black nanopowder was approximately 30 nm, the DBP oil absorption was 86 cc/100 g, the specific surface area was greater than or equal to about 75 m²/g, and the purity was greater than or equal to about 99.9%.

### Reference Example 3: Synthesis of ZnMgO Nanoparticles

Zinc acetate dihydrate and magnesium acetate tetrahydrate were added to a reaction vessel containing dimethyl sulfoxide and heated to 60° C. in air. Subsequently, an ethanol solution of tetramethylammonium hydroxide pentahydrate was added to the reaction vessel. After stirring for 1 hour, the resulting precipitate (Zn₁₋ₓMgₓO nanoparticles) was centrifuged and dispersed in ethanol to obtain Zn₁₋ₓMgₓO nanoparticles (x=0.15).

Transmission electron microscopy analysis was performed on the obtained nanoparticles. As a result, the average size of the particles was confirmed to be approximately 3 nm.

### Example 1

An electroluminescent device (ITO/PEDOT:PSS (30 nm)/TFB (25 nm)/QD emission layer (20 nm)/ETL (20 nm)/Al (100 nm)) was produced according to the following method.

A semiconductor nanoparticle dispersion was obtained by dispersing the semiconductor nanoparticle obtained in Reference Example 1 in octane (OD: 0.4). Carbon nanoparticles prepared in Reference Example 2 (5 mg) were dispersed in 10 mL of octane and subjected to sonification for 5 minutes to obtain a carbon nanoparticle dispersion. The semiconductor nanoparticle dispersion and the carbon nanoparticle dispersion were mixed to obtain a composition for forming an emission layer. An ETL dispersion was prepared by dispersing the zinc magnesium oxide nanoparticles prepared in Reference Example 3 in ethanol. In the composition for forming an emission layer, the content of carbon nanoparticles was 0.67 wt % based on the total weight of the semiconductor nanoparticles.

According to photoluminescence analysis of the semiconductor nanoparticle dispersion and the prepared composition for forming an emission layer, it was confirmed that mixing the carbon nanoparticle dispersion with the semiconductor nanoparticle dispersion did not induce substantial PL quenching.

After surface-treating a glass substrate deposited with ITO with UV-ozone for 15 minutes, a PEDOT:PSS solution (H.C. Starks, Inc.) was spin-coated thereon and heat-treated at 150° C. for 10 minutes under an air atmosphere and then, at 150° C. for 20 to 30 minutes under an N₂ atmosphere to form a 30 nm-thick hole injection layer.

On the hole injection layer, a poly[(9,9-dioctylfluorenyl-2,7-diyl-co (4,4′-(N-4-butylphenyl)diphenylamine] solution (TFB) (Sumitomo Corp.) was spin-coated and heat-treated at 150° C. for 30 minutes, forming a 25 nm-thick hole transport layer.

On the hole transport layer, the composition for forming an emission layer was spin-coated and heat-treated at 150° C. for 30 minutes, forming a 20 nm-thick emission layer.

On the emission layer, the ETL dispersion was spin-coated and heat-treated for 30 minutes, forming an electron transport layer (thickness: 20 nm).

On the obtained electron transport layer, aluminum (Al) was vacuum-deposited to be 100 nm thick, forming a second electrode and thus producing an electroluminescent device.

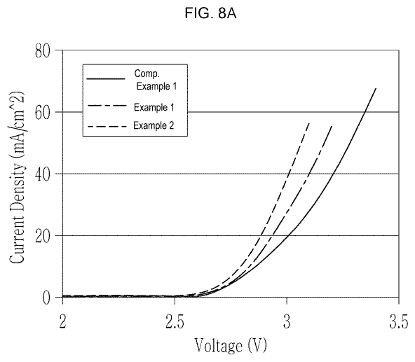

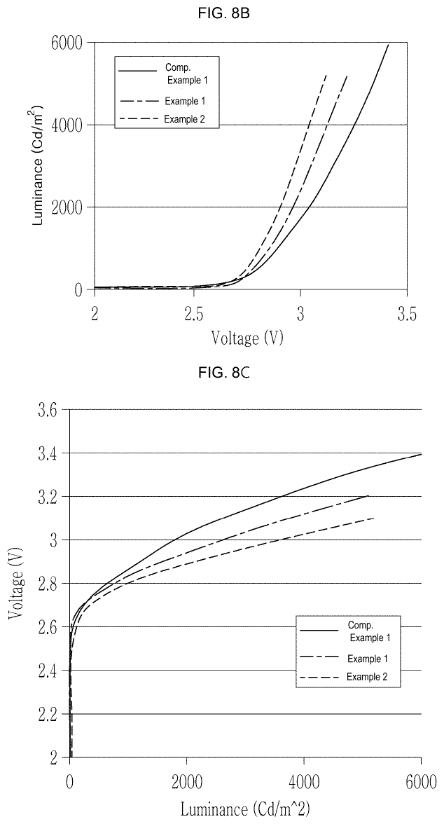

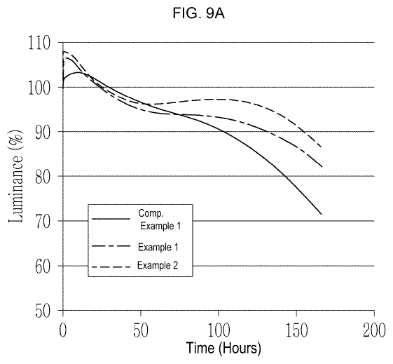

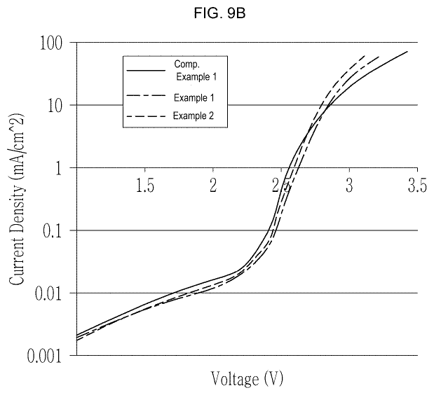

The electroluminescent properties and lifetime characteristics of the fabricated light emitting device were measured, and the results are summarized in Table 1 and FIG. 8A, FIG. 8B, FIG. 8C, FIG. 9A, and FIG. 9B.

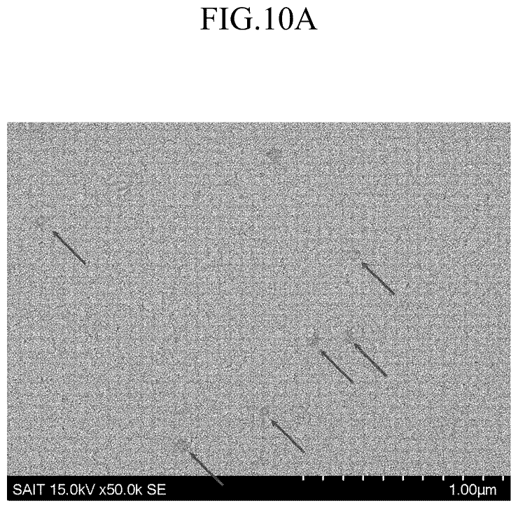

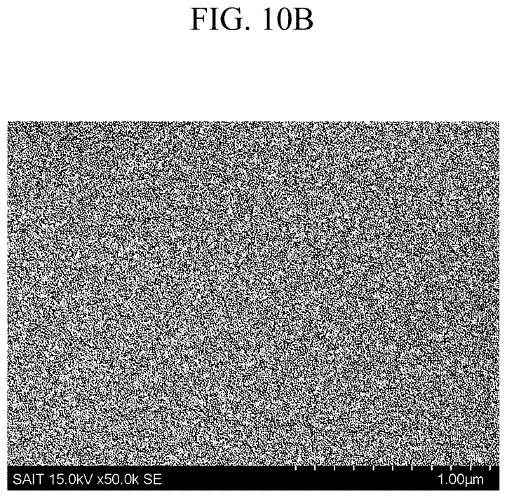

Scanning electron microscopy analysis was performed on the surface of the fabricated emission layer, and the results are shown in FIG. 10A.

### Example 2

An electroluminescent device was fabricated in the same manner as in Example 1, except that 5 mg of the carbon nanoparticles prepared in Reference Example 2 were dispersed in 10 mL of octane, subjected to sonification for 5 minutes, and then diluted with ten times the volume of octane to obtain a carbon nanoparticle dispersion.

The electroluminescent properties and lifetime characteristics of the fabricated light emitting device were measured, and the results are summarized in Table 1 and FIG. 8A, FIG. 8B, FIG. 8C, FIG. 9A, and FIG. 9B.

### Comparative Example 1

An electroluminescent device was fabricated in the same manner as in Example 1, except that the semiconductor nanoparticle dispersion was used as the composition for forming an emission layer without mixing with the carbon nanoparticle dispersion.

The electroluminescent properties and lifetime characteristics of the fabricated light emitting device were measured, and the results are summarized in Table 1 and FIG. 8A, FIG. 8B, FIG. 8C, FIG. 9A, and FIG. 9B.

Scanning electron microscopy analysis was performed on the surface of the fabricated emission layer, and the results are shown in FIG. 10B.

TABLE 1

| | EQE max | Cd/A max | T90 |
|---|---|---|---|
| Comp. Example 1 | 8.7 | 8.3 | 103.88 |
| Example 1 | 9.0 | 7.6 | 133.31 |
| Example 2 | 9.1 | 7.4 | 155.40 |

EQE max: maximum external quantum efficiency
Cd/A max: maximum current efficiency

From the results shown in Table 1 and FIG. 9A, it can be confirmed that the electroluminescent device of the Examples exhibits enhanced electroluminescent properties and extended lifetime characteristics compared to the electroluminescent device of the Comparative Example.

From the results of FIG. 8A and FIG. 8B, it can be confirmed that the electroluminescent device of the Examples exhibits a higher current density or luminance at a given voltage compared to the electroluminescent device of the Comparative Example.

From the results of FIG. 8C, it can be confirmed that the electroluminescent device of the Examples shows a smaller voltage increase (ΔV) with increasing luminance compared to the electroluminescent device of the Comparative Example.

From the results of FIG. 9B, it can be confirmed that the electroluminescent device of the Examples exhibits substantially the same result as the electroluminescent device of the Comparative Example in terms of leakage current.

From the results of FIG. 10A and FIG. 10B, it can be confirmed that assemblies of carbon nanoparticles (50 to 100 nm) are present in the emission layer of the electroluminescent device of the Examples, while such assemblies of carbon nanoparticles are not present in the emission layer of the electroluminescent device of the Comparative Example.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

1. An electroluminescent device comprising:
a first electrode and a second electrode, which are spaced apart from each other; and
an emission layer disposed between the first electrode and the second electrode,
wherein the emission layer is configured to emit first light having a predetermined peak emission wavelength,
wherein the emission layer comprises a semiconductor nanoparticle and a carbon nanoparticle, and
wherein the carbon nanoparticle has a dimension greater than or equal to about 2 nanometers (nm) and less than or equal to about 50 nm.

2. The electroluminescent device of claim 1, wherein
the dimension of the carbon nanoparticle is greater than or equal to about 10 nm and less than or equal to about 45 nm.

3. The electroluminescent device of claim 1, wherein the dimension of the carbon nanoparticle is greater than or equal to about 20 nm and less than or equal to about 40 nm.

4. The electroluminescent device of claim 1, wherein the predetermined peak emission wavelength is greater than or equal to about 440 nm and less than or equal to about 480 nm.

5. The electroluminescent device of claim 1, wherein the semiconductor nanoparticle does not comprise cadmium, and
wherein the semiconductor nanoparticle comprises a silver indium gallium sulfide, an indium phosphide, an indium zinc phosphide, a zinc chalcogenide, or a combination thereof.

6. The electroluminescent device of claim 1, wherein the carbon nanoparticle comprises a carbon black, a graphite nanopowder, a graphene nanoparticle, a graphene oxide nanoparticle, or a combination thereof.

7. The electroluminescent device of claim 1, wherein the carbon nanoparticle comprises amorphous carbon, paracrystalline carbon, or a combination thereof.

8. The electroluminescent device of claim 1, wherein the carbon nanoparticle is a plate-like material comprising crystalline carbon.

9. The electroluminescent device of claim 1, wherein the carbon nanoparticle has a specific surface area greater than or equal to about 20 square-meters per gram (m²/g) and less than or equal to about 1200 m²/g.

10. The electroluminescent device of claim 1, wherein the carbon nanoparticle in the emission layer is provided as an assembly of a plurality of carbon nanoparticles, and
wherein the assembly has a dimension of greater than or equal to about 30 nm and less than or equal to about 500 nm.

11. The electroluminescent device of claim 10, wherein the dimension of the assembly is greater than or equal to about 50 nm and less than or equal to about 120 nm.

12. The electroluminescent device of claim 1,
wherein the semiconductor nanoparticle comprises a zinc chalcogenide, and wherein a mole ratio of carbon to zinc in the emission layer is greater than or equal to about 0.3:1 and less than or equal to about 1000:1.

13. The electroluminescent device of claim 1,
wherein the semiconductor nanoparticle comprises zinc and selenium, and wherein a mole ratio of carbon to selenium in the emission layer is greater than or equal to about 0.2:1 and less than or equal to about 1000:1.

14. The electroluminescent device of claim 1,
wherein the first light is blue light,
wherein the semiconductor nanoparticle comprises a first semiconductor nanocrystal comprising zinc and selenium and a second semiconductor nanocrystal comprising zinc and sulfur, and
wherein the carbon nanoparticle comprises conductive carbon black.

15. A method of manufacturing the electroluminescent device of claim 1, the method comprising:
forming one of the first electrode and the second electrode;
forming the emission layer on the formed electrode; and
forming the other one of the first electrode and the second electrode on the emission layer,
wherein forming the emission layer comprises:
obtaining a composition for forming the emission layer, which comprises the carbon nanoparticle and the semiconductor nanoparticle in an organic solvent; and
applying the composition for forming the emission layer to form the emission layer.

16. The method of claim 15, wherein the composition for forming the emission layer does not comprise an insulating polymer or a monomer thereof.

17. The method of claim 15, wherein the carbon nanoparticle is heat-treated at a temperature greater than or equal to about 80° C. and less than or equal to about 500° C. before being added to the organic solvent.

18. The method of claim 15, wherein obtaining the composition for forming the emission layer comprises preparing a dispersion in which the semiconductor nanoparticle, the carbon nanoparticle, or both are dispersed in the organic solvent, and performing sonication on the prepared dispersion.

19. A display device comprising the electroluminescent device of claim 1.

20. The electroluminescent device of claim 1, wherein the carbon nanoparticle is non-luminous.
